(19) United States
(12) Patent Application Publication
(10) Pub. No.: US 2026/0096208 A1
(43) Pub. Date: Apr. 2, 2026

(54) CELL REGION HAVING VG-CONTACT-FREE AND VD-CONTACT-FREE TRACKS AND METHOD OF MANUFACTURING SAME

(71) Applicant: TAIWAN SEMICONDUCTOR MANUFACTURING COMPANY, LTD., Hsinchu (TW)

(72) Inventors: Kuan Yu CHEN, Hsinchu (TW); Wei-Cheng TZENG, Hsinchu (TW); Yu-Rong CHEN, Hsinchu (TW); Hung-Li CHIANG, Hsinchu (TW); Wei-Cheng LIN, Hsinchu (TW); Jiann-Tyng TZENG, Hsinchu (TW)

(21) Appl. No.: 18/999,878

(22) Filed: Dec. 23, 2024

Related U.S. Application Data
(60) Provisional application No. 63/700,309, filed on Sep. 27, 2024.

(51) Int. Cl. H10D 84/90

(52) U.S. Cl. CPC H10D 84/975; H10D 84/981; H10D 84/985

(57) ABSTRACT

A cell region (of a device) includes: active regions; gate segments and metal-to-source/drain-region (MD) contacts which are interspersed; via-to-gate (VG) contacts; via-to-MD-contact (VD) contacts; the VG contacts and the VD contacts being aligned correspondingly to alpha tracks extending in the first direction; first routing (RTE) segments aligned correspondingly to the alpha tracks; and first buried power grid segments; and first and second ones of the alpha tracks being adjacent to first and second boundaries of the cell region; at least a third one of the alpha tracks being between the first and second alpha tracks; the first alpha track being free from having any of the VG contacts aligned thereto; and the second alpha track being free from having any of the VD contacts aligned thereto.

### PRIORITY CLAIM

The application claims the priority of U.S. Provisional Application No. 63/700,309, filed Sep. 27, 2024, which is incorporated herein by reference in its entirety.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a block diagram, in accordance with some embodiments.

FIGS. 2A-2E are corresponding layout diagrams, in accordance with some embodiments.

FIGS. 3A-3C are corresponding layout diagrams, in accordance with some embodiments.

FIGS. 4A-4B are corresponding cross-sections, in accordance with some embodiments.

FIG. 5A is a layout diagram, in accordance with some embodiments.

FIGS. 5B-5C are corresponding block diagrams, in accordance with some embodiments.

FIGS. 6 and 7A-7B are flowcharts of corresponding methods, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a cell region (of a device) includes: active regions extending in a first direction; gate segments and metal-to-source/drain-region (MD) contacts which extend in a second direction perpendicular to the first direction, are interspersed, and have portions over areas of the active regions; via-to-gate (VG) contacts over areas of the gate segments; via-to-MD-contact (VD) contacts over areas of the MD contacts; the VG contacts and the VD contacts over being aligned correspondingly to alpha tracks extending in the first direction; in a first layer of metallization, first routing (RTE) segments which extend in the first direction, are aligned correspondingly to the alpha tracks, and are correspondingly over the VG contacts or the VD contacts; and in a first buried layer of metallization on a second side of the active regions, first buried power grid segments which extend in the first direction; and first (e.g., top alpha track) and second (e.g., bottom alpha track) ones of the alpha tracks being adjacent to first (e.g., top) and second (e.g., bottom) boundaries of the cell region; at least a third one (e.g., interior alpha tracks) one of the alpha tracks being between the first and second alpha tracks; the first alpha track being free from having any of the VG contacts aligned thereto; and the second alpha track being free from having any of the VD contacts aligned thereto. Such a cell region is an example of a back side power delivery (BSPD) architecture.

According to another approach for producing a device having a BSPD architecture, for each of various spatial relationships (e.g., counterpart VG spacing, counterpart VD spacing, counterpart V0 structure spacing, or the like), the counterpart minimum spacing requires the use of two EUVL masks to produce the spatial relationship. By contrast, at least some embodiments use larger minimum spacing for each of corresponding spatial relationships. In some embodiments, for each of the corresponding spatial relationships, one EUVL mask is sufficient to produce the spatial relationship in a device having a BSPD architecture due at least in part to one or more of the design rules disclosed herein. By eliminating one EUVL mask, such embodiments at least are less expensive and/or faster to manufacture as compared to the other approach.

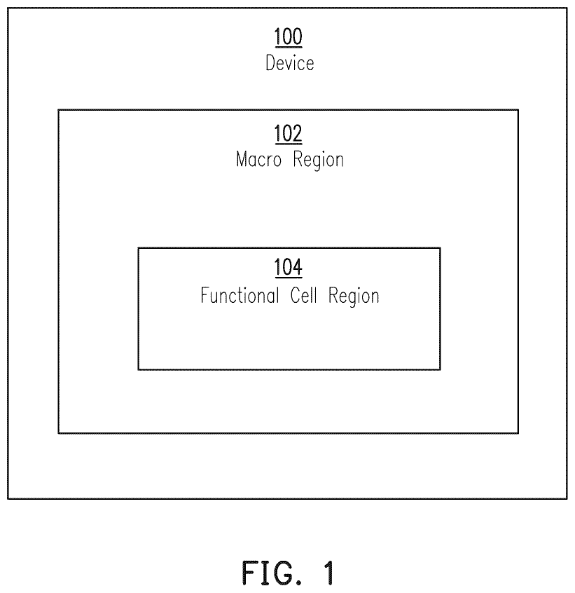

FIG. 1 is a block diagram of a cell region 104 of a device 100, in accordance with some embodiments.

Device 100 is an example of an integrated circuit (IC). In some embodiments, device 100 is referred to as a semiconductor device. Device 100 includes a macro region 102. In some embodiments, macro region 102 is comprised of one or more functional regions, e.g., circuit regions, or the like. In some embodiments, macro region 102 includes one or more of a memory, a power grid, a cell or cells, an inverter, a latch, a buffer, a driver, analog devices such as a digital-to-analog converter (DAC) or an analog-to-digital converter (ADC) or the like, clock trees, phase locked loops (PLLs), interfaces and/or any other type of circuit arrangement. Example memories include a static random access memory (SRAM), a dynamic RAM (DRAM), a resistive RAM, a magnetoresistive RAM (MRAM), a read only memory (ROM), or the like.

Macro region 102 is representable digitally in a library of standard cells. In some embodiments, macro region 102 is understood in the context of an analogy to the architectural hierarchy of modular programming, in which subroutines/procedures are called by a main program (or by other subroutines) to carry out a given computational function. In this context, device 100 uses macro region 102 to perform one or more given functions. Accordingly, in this context and in terms of architectural hierarchy, device 100 is analogous to the main program and macro region 102 is analogous to subroutines/procedures. In some embodiments, macro region 102 is a soft macro. In some embodiments, macro region 102 is a hard macro. In some embodiments, macro region 102 is a soft macro which is described digitally in register-transfer level (RTL) code. In some embodiments, synthesis, placement, and routing have yet to have been performed on macro region 102 such that the soft macro can be synthesized, placed, and routed for a variety of process technology nodes. In some embodiments, macro region 102 is a hard macro which is described digitally in a binary file format (e.g., Graphic Database System II (GDSII) stream format), where the binary file format represents planar geometric shapes, text labels, other information, and the like of one or more layouts of macro region 102 in hierarchical form. In some embodiments, a binary file format is referred to as a non-text file format. In some embodiments, synthesis, placement, and routing have been performed on macro region 102 such that the hard macro is specific to a particular process technology node.

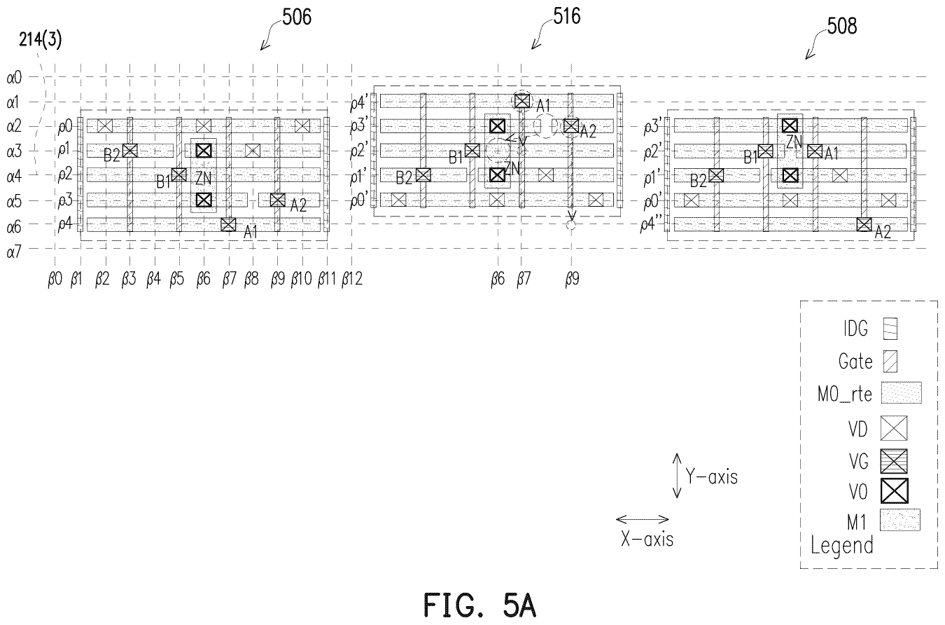

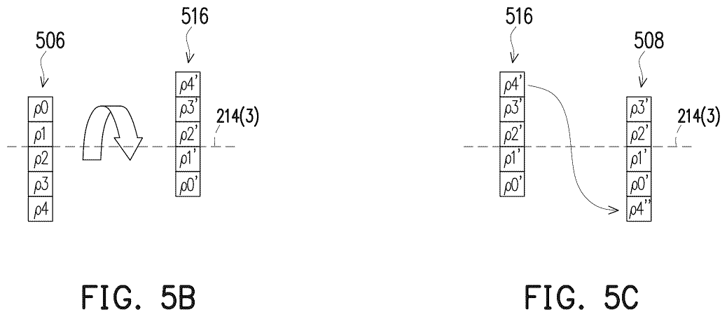

In FIG. 1, macro region 102 includes a functional cell region 104 that represents a functional circuit. Functional cell region 104 includes at least one active device such as a transistor or the like. In some embodiments, functional cell region 104 includes one or more logic gates. In some embodiments, functional cell region 104 is or includes a buffer, a driver, an inverter, or the like. Examples of logic gates/circuits include circuits configured to perform logic functions AND, OR, NAND, NOR, XOR, INV, AND-OR-Invert (AOI) (see, e.g., FIG. 5A), OR-AND-Invert (OAI), or the like. Examples of other functional circuits include a multiplexer (MUX), flip-flop, buffer (BUFF), driver (DRV), latch, delay, clock, memory, or the like.

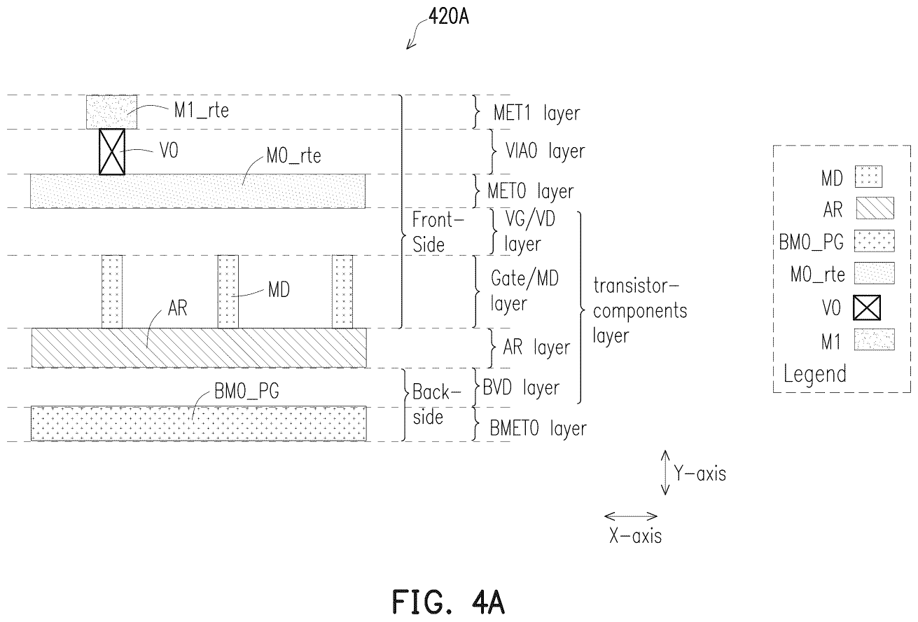

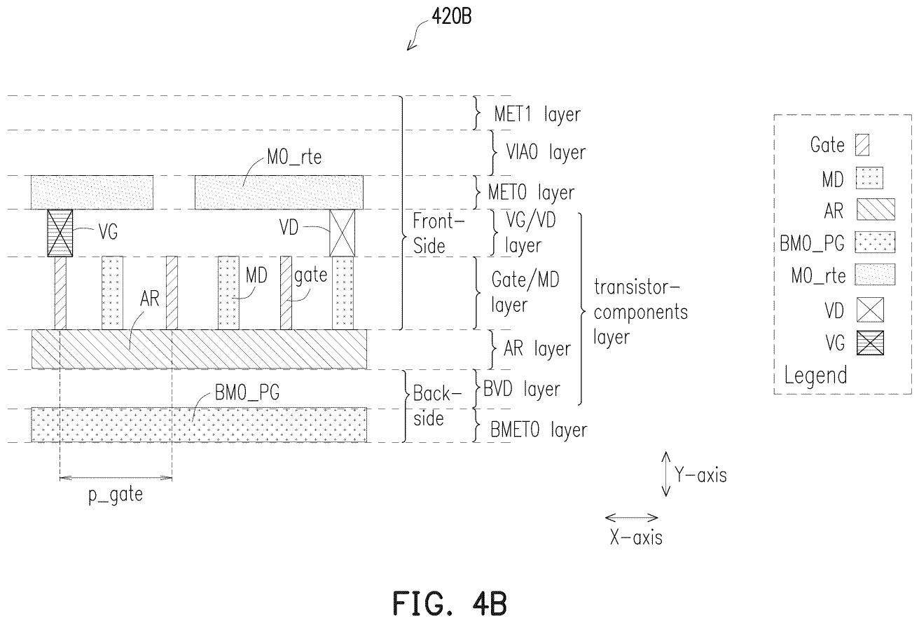

Functional cell region 104 includes corresponding segments in one or more metallization layers (see, e.g., FIGS. 4A-4B). Figures of the present disclosure assume a Cartesian coordinate system (unless noted otherwise) in which first, second and third directions are, e.g., correspondingly parallel to the X-axis, the Y-axis and the Z-axis. In some embodiments, the first to third directions correspond to directions other than the X-axis, Y-axis and Z-axis. In some embodiments, long and short axes of the segments extend correspondingly in the first and second directions in even ones of the metallization layers; in such embodiments, long and short axes of the segments extend correspondingly in the second and first directions in odd ones of the metallization layers. In such embodiments, boundaries of functional cell region 104 are described in terms of the first and second directions.

In some embodiments, functional cell region 104 corresponds to a transistor-components layer (see, e.g., FIGS. 4A-4B) having circuitry components, e.g., transistor, formed thereon in a front-end-of-line (FEOL) fabrication. In functional cell region 104, above and/or below an active region (AR) layer (see, e.g., FIGS. 4A-4B), various metal layers (see, e.g., FIGS. 4A-4B) are interleaved with corresponding interconnection layers (see, e.g., FIGS. 4A-4B) are stacked over and/or under insulating layers in a back end of line (BEOL) fabrication. The BEOL fabrication provides a power network and/or routing for circuitry of device 100, including macro region 102 and functional cell region 104.

In some embodiments, functional cell region 104 includes one or more active devices, passive devices, or the like. Examples of active devices or active elements include, but are not limited to, transistors, diodes, or the like. Examples of passive elements include, but are not limited to, capacitors, inductors, fuses, resistors, or the like.

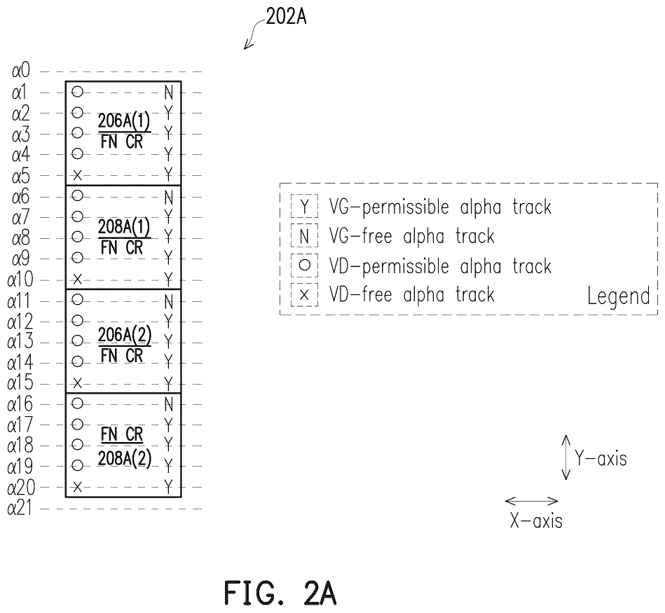

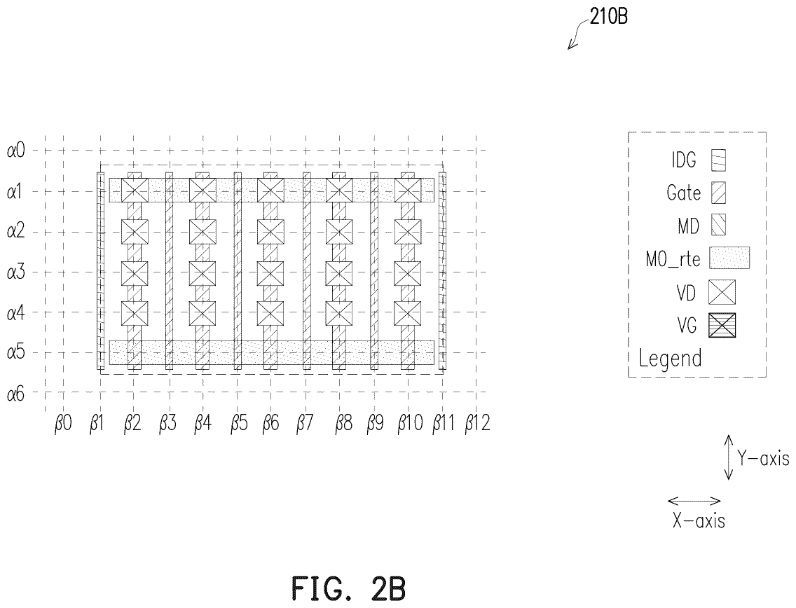

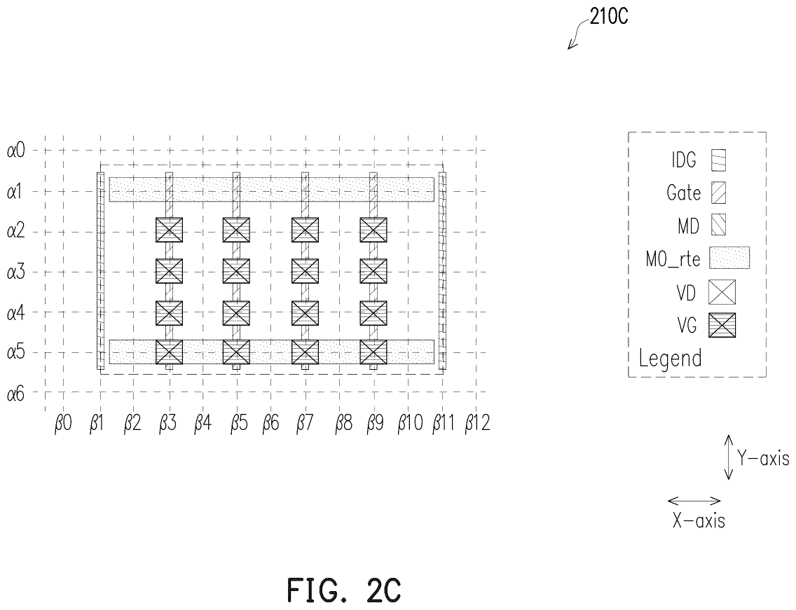

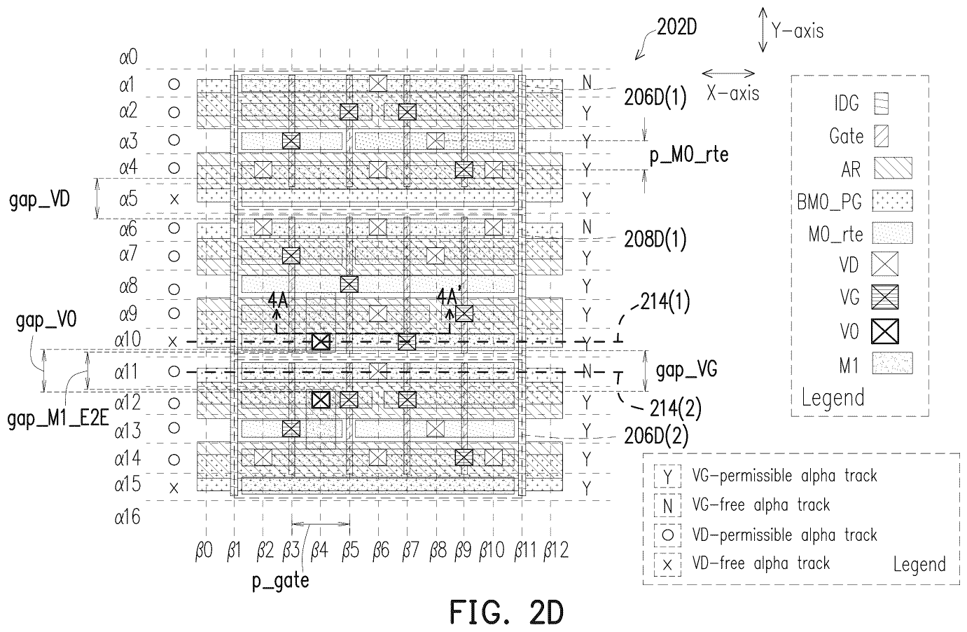

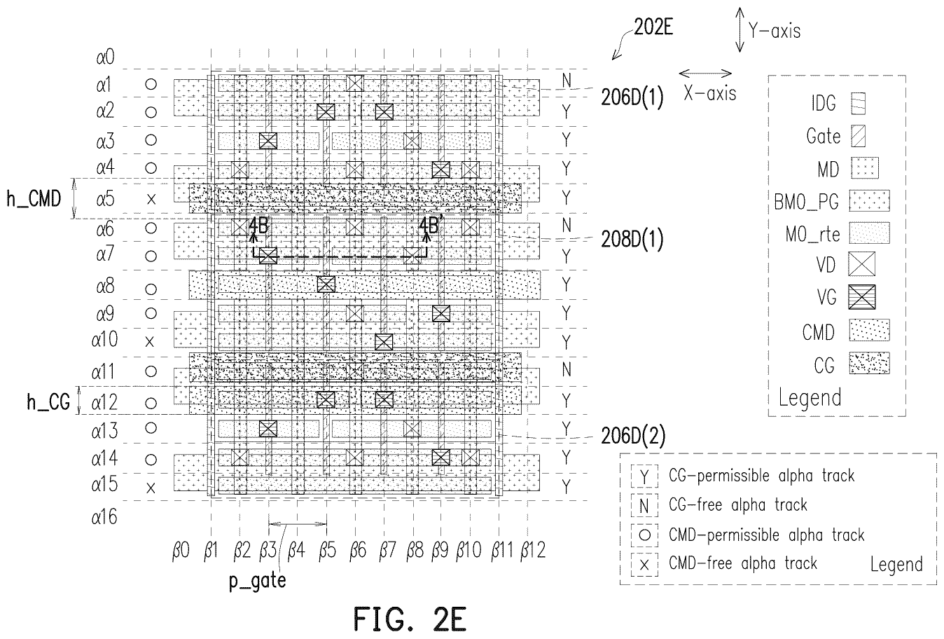

FIG. 2A is a layout diagram of a macro region macro region 202A, in accordance with some embodiments.

Macro region Macro region 202A is an example of macro region 102 of FIG. 1. Macro region 202A is arranged relative to alpha track lines α0-α21 that extend parallel to the X-axis. In FIG. 2A, and in other layout diagrams disclosed herein, the first and second directions are assumed to be parallel correspondingly to the X-axis and the Y-axis. In some embodiments, the first and second directions are assumed to have orientations other than being parallel correspondingly to the X-axis and the Y-axis. In FIG. 2A, and in other layout diagrams disclosed herein, rows are collinear with the alpha track lines.

Macro region 202A includes functional (FN) cell regions 206A(1)-206A(2) and 208A(1)-208A(2) which are stacked relative to the Y-axis. Functional cell region 206A(2) is stacked on functional cell region 208A(2). Functional cell region 208A(1) is stacked on functional cell region 206A(2). Functional cell region 206A(1) is stacked on functional cell region 208A(1). Functional cell regions 206A(1)-206A(2) and 208A(1)-208A(2) are also described as being interleaved or interspersed relative to the Y-axis.

Each of functional cell regions 206A(1)-206A(2) and 208A(1)-208A(2) is configured to perform a given function, e.g., AOI (see, e.g., FIG. 5A). That is, each of functional cell regions 206A(1)-206A(2) and 208A(1)-208A(2) is configured to perform the same function.

The components (see, e.g., FIGS. 2B-2E) on a front side of an active region layer (see, e.g., FIGS. 4A-4B) in each of functional cell regions 206A(1)-206A(2) and 208A(1)-208A(2) include: gate segments (see, e.g., FIGS. 2C-2E) in a gate/MD layer (see, e.g., FIGS. 4A-4B); metal-to-source/drain-region (MD) contacts (see, e.g., FIGS. 2C-2E) in the gate/MD layer; via-to-gate (VG) contacts (see, e.g., FIGS. 2C and 2D-2E) in a VG/VD layer (see, e.g., FIGS. 4A-4B); via-to-MD-contact (VD) contacts (see, e.g., FIGS. 2B and 2D-2E) in the VG/VD layer; and first routing (RTE) segments in a first layer of metallization (see, e.g., FIGS. 4A-4B). In some embodiments, VG is an acronym for via on gate. In some embodiments, VD is an acronym for via on source/drain.

In some embodiments, depending upon the numbering convention of the corresponding process technology node by which a device is to be fabricated, on a front side (see, e.g., FIGS. 4A-4B) of the active region layer (see, e.g., FIGS. 4A-4B), the first layer metallization is either metallization layer zero (MET0) (see, e.g., FIGS. 4A-4B) or metallization layer one (MET1), and correspondingly a first interconnection layer on the first metallization layer is either interconnection layer zero (VIA0) (see, e.g., FIGS. 4A-4B) or interconnection layer one (VIA1).

In such embodiments, again depending upon the numbering convention of the corresponding process technology node, components on a back side (see, e.g., FIGS. 4A-4B) of the active region layer (see, e.g., FIGS. 4A-4B) include buried via-to-source/drain-region (BVD) contacts (see, e.g., FIGS. 2B and 2D-2E) in a BVD layer and the first buried power grid segments in the first buried metallization layer. The first buried metallization layer is either buried metallization layer zero (BMET0) (see, e.g., FIGS. 4A-4B) or buried metallization layer one (BMET1), and correspondingly a first buried interconnection layer under the first metallization layer is either interconnection layer zero (VIA0) (see, e.g., FIGS. 4A-4B) or interconnection layer one (VIA1).

In FIG. 2A, and in the other figures disclosed herein, the following nomenclature is adopted: the first metallization layer is assumed to be MET0; the first interconnection layer is assumed to be VIA0; the second metallization layer is assumed to be MET1; the second interconnection layer is assumed to be VIA1; and the third metallization layer is assumed to MET2. Metallization segments in layer MET0 are referred to as M0 segments. Via structures in layer VIA0 are referred to as V0 structures. Metallization segments in layer MET1 are referred to as M1 segments. Via structures in layer VIA1 are referred to as V1 structures. Metallization segments in layer MET2 are referred to as M2 segments.

Looking ahead to FIGS. 2D-2E and 4A-4B, or the like, the following nomenclature is also adopted: the first buried metallization layer is assumed to be BMET0; the first buried interconnection layer is assumed to be BVIA0; the second buried metallization layer is assumed to be BMET1; the second buried interconnection layer is assumed to be BVIA1; and the third buried metallization layer is assumed to BMET2. Metallization segments in layer BMET0 are referred to as buried M0 segments. Via structures in layer BVIA0 are referred to as BV0 structures. Metallization segments in layer BMET1 are referred to as BM1 segments. Via structures in layer BVIA1 are referred to as BV1 structures. Metallization segments in layer BMET2 are referred to as BM2 segments.

The discussion will now return to FIG. 2A.

In FIG. 2A, and in the other figures disclosed herein: the gate segments and the MD contacts are aligned to corresponding ones of beta track lines; and the VG contacts and the VD contacts are aligned to corresponding ones of alpha track lines and the beta track lines.

Functional cell regions 206A(1)-206A(2) are instances of a first arrangement of components that is configured to perform the given function. Functional cell regions 208A(1)-206A(2) are instances of a second arrangement of components that is configured to perform the given function. The first and second arrangements facilitate the interleaved/interspersed stacking of functional cell regions 206A(1)-206A(2) and 208A(1)-208A(2), relative to the Y-axis.

In some embodiments, the first and second arrangements refer to corresponding arrangements of the gate segments, MD contacts, VG contacts and VD contacts. In some embodiments, the first and second arrangements refer to corresponding arrangements of the gate segments, MD contacts, VG contacts and VD contacts, plus routing ones of the M0 segments (M0_rte segments) (see, e.g., FIGS. 2D and 5A) and the V0 structures.

Examples of differences between the first and second arrangements are discussed below, and also include differences shown in FIGS. 2D-2E, functional cell regions 506 and 508 of FIG. 5A, or the like. Despite the first and second arrangements being different, nevertheless, the first and second arrangements have properties in common. A first property common to the first and second arrangements is that the gate segments and VG contacts are aligned to corresponding odd ones of the beta track lines (e.g., beta track lines β3-β9 of FIGS. 2D-2E). A second property common to the first and second arrangements is that the MD contacts and VD contacts are aligned to corresponding even ones of the beta track lines (e.g., beta track lines β2-β10 of FIGS. 2D-2E). A third property common to the first and second arrangements is shown in FIGS. 2B-2C.

FIGS. 2B-2C are layout diagrams of corresponding functional cell region 210B-210C, in accordance with some embodiments.

The layout diagrams correspondingly of FIGS. 2B-2C, and other layout diagrams disclosed herein, are representative of a transistor-based device. Structures in the device are represented by patterns (also known as shapes) in the layout diagram. For simplicity of discussion, elements in the layout diagrams correspondingly of FIGS. 2B-2C (and also in other layout diagrams disclosed herein) will be referred to as if they are structures rather than patterns. For example, shapes in FIG. 2B representing instances of M0_rte segments are referred to as M0_rte segments per se rather than patterns.

A layout diagram is a top view. Shapes in the layout diagram are two-dimensional relative to, e.g., the X-axis and the Y-axis, whereas the device being represented is three-dimensional. As such, a shape in such layout diagrams is described as having a width/length relative to the X-axis and a height relative to the Y-axis. Relative to the Z-axis, e.g., a bottom/back side of a first component being represented in the layout diagram is stacked on a top/front side of a second component device being represented in the layout diagram, or a top/front back side of the first component is stacked, e.g., under a bottom/back side of the second component.

Typically, relative to the Z-axis, the device is organized as a stack of layers in which are located corresponding structures, i.e., to which belong corresponding structures. Each shape in the layout diagram represents, more particularly, a component in a corresponding layer of the corresponding device. Also, typically, the layout diagram represents relative depth, i.e., positions along the Z-axis, of shapes and corresponding layers by superimposing a second shape on a first shape so that the second shape at least partially overlaps the first shape. For simplicity of illustration, some structures which have a first order of stacking along the Z-axis in the device are represented in the layout diagram using a second order of stacking along the Z-axis, i.e., a different/distorted stacking order; for example, see FIG. 2I.

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding device are represented, i.e., selected layers of the layout diagram are omitted, e.g., for simplicity of illustration. Alternatively, and/or additionally, in some circumstances, not all elements of a given depicted layer of the corresponding device are represented, i.e., selected elements of the given depicted layer of the layout diagram are omitted, e.g., for simplicity of illustration. FIGS. 2B-2C and the other layout diagrams disclosed herein are examples of layout diagrams in which selected layers and/or selected elements of depicted given layers, have been omitted.

Regarding FIGS. 2B-2C, each of functional cell regions 210B and 210C is an example of functional cell regions 206A(1)-206A(2) and 208A(1)-208A(2) of FIG. 2A.

Functional cell regions 210B-210C are representations of corresponding first and second design rules (DRs) that result in the first and second arrangements of FIG. 2A, as discussed below.

Regarding FIGS. 2A-2B, the first design rule relates to a first one of the alpha tracks, e.g., the alpha track which is adjacent to the bottom boundary of functional cell region 210B relative to the Y-axis and which overlaps functional cell region 210B. In the context of functional cell regions 206A(1)-206A(2) and 208A(1)-208A(2) of FIG. 2A and 210B of FIG. 2B, the first alpha track is referred to as the bottom alpha track. In FIGS. 2A-2C, the bottom alpha tracks are assumed to be alpha tracks α5, α10, α15 and α20. The first design rule specifies that the bottom alpha track is to be free of having any VD contact aligned thereto. In some embodiments, the first design rule is referred to as a VD-non-grata-track design rule.

Regarding FIGS. 2A and 2C, the second design rule relates to a second one of the alpha tracks, e.g., the alpha track which is adjacent to the top boundary of functional cell region 210C relative to the Y-axis and which overlaps functional cell region 210C. In the context of functional cell regions 206A(1)-206A(2) and 208A(1)-208A(2) of FIG. 2A and 210C of FIG. 2C, the second alpha track is referred to as the top alpha track. In FIGS. 2B-2C, the top alpha tracks are assumed to be alpha track α1, α6, all and α16. The second design rule specifies that the top alpha track is to be free of having any VG contact aligned thereto. In some embodiments, the second design rule is referred to as a VG-non-grata-track design rule.

In functional cell regions 206A(1)-206A(2) and 208A(1)-208A(2) of FIG. 2A and 210B of FIG. 2C, VD contacts are permissible in the top alpha track and in each of the interior alpha tracks that is between the top alpha track and the bottom alpha track. For example, the interior alpha tracks are alpha tracks α2-α4 in each of FIGS. 2B-2C. In other words, in functional cell regions 206A(1)-206A(2) and 208A(1)-208A(2) of FIG. 2A and 210B of FIG. 2B, each of alpha tracks α1-α4 is a VD-permissible alpha track.

In functional cell regions 206A(1)-206A(2) and 208A(1)-208A(2) of FIG. 2A and 210C of FIG. 2C, VG contacts are permissible in the bottom alpha track and in each of the interior alpha tracks. In other words, in functional cell regions 206A(1)-206A(2) and 208A(1)-208A(2) of FIG. 2A and 210C of FIG. 2C, each of alpha tracks α2-α5 is a VG-permissible alpha track.

The third property common to the first and second arrangements, mentioned above in the discussion of FIG. 2A, is shown (again) in FIGS. 2B-2C. In each of functional cell regions 210B and 210C, VG contacts are permissible in each of the interior alpha tracks, namely alpha tracks α2 -α4 in each of FIGS. 2B-2C. In each of functional cell regions 210B and 210C, VD contacts are permissible in each of the interior alpha tracks, namely (again) alpha tracks α2-α4 in each of FIGS. 2B-2C. Hence, the third property common to the first and second arrangements is that VG contacts and/or VG contacts are permissible in each of alpha tracks α2-α4 in each of FIGS. 2B-2C. In other words, as shown in FIGS. 2B-2C, the third property common to the first and second arrangements is that each of alpha tracks α2-α4 is a VD-permissible alpha track and a VG-permissible alpha track.

FIG. 2D is a layout diagram of a macro region 202D, in accordance with some embodiments.

Macro region 202D is an example of macro region 102 of FIG. 1. Macro region 202D includes functional (FN) cell regions 206D(1)-206D(2) and 208D(1) which are stacked relative to the Y-axis. In FIG. 2D, section line 4A-4A′ extends parallel to the X-axis. In some embodiments, section line 4A-4A′ of FIG. 2D corresponds to cross-section 420A of FIG. 4A.

Functional cell region 208D(1) is stacked on functional cell region 206D(2). Functional cell region 206D(1) is stacked on functional cell region 208D(1). Functional cell regions 206D(1)-206D(2) and 208D(1) are also described as being interleaved relative to the Y-axis.

Each of functional cell regions 206D(1)-206D(2) and 208D(1) is configured to perform a given function. That is, each of functional cell regions 206D(1)-206D(2) and 208D(1) is configured to perform the same function. Nevertheless, there are differences regarding the arrangement of components in functional cell regions 206D(1)-206D(2) as compared to the arrangement of components in functional cell region 208D(1), as discussed below.

The components included in each of functional cell regions 206D(1)-206D(2) and 208D(1) include: active regions (ARs); gate segments; MD contacts; VG contacts; VD contacts; M0_rte segments; V0 structures; routing ones of the M1 segments (M1_rte segments); isolation dummy gates (discussed below); and power grid (PG) ones of BM0 segments (BM0_PG segments).

Due to the inclusion of BM0_PG segments, each of functional cell regions 206D(1)-206D(2) and 208D(1) is an example of a back side power delivery (BSPD) architecture. FIG. 2D assumes that each of functional cell regions 206D(1)-206D(2) and 208D(1) is free of any of the M0 segments being PG segments. Benefits of a BSPD architecture include reduced congestion of M0_rte segments on the front side, or the like. In some embodiments, selected ones of the M0 segments are PG segments (M0_PG segments).

In some embodiments in which the first and second arrangements refer to corresponding arrangements of the gate segments, MD contacts, VG contacts and VD contacts: functional cell regions 206D(1)-206D(2) are instances of a first arrangement of components that is configured to perform the given function; and functional cell region 208D(1) is an instance of a second arrangement of components that is configured to perform the given function.

In FIG. 2D, functional cell region 206D(2) includes a V0 structure and an M1_rte segment whereas functional cell region 206D(1) does not. In some embodiments in which the first and second arrangements refer to corresponding arrangements of the gate segments, MD contacts, VG contacts, VD contacts; V0 structures and M1_rte segments: functional cell region 206D(2) is an instance of a first arrangement of components that is configured to perform the given function; functional cell region 208D(1) is an instance of a second arrangement of components that is configured to perform the given function; and functional cell region 206D(1) is a slight variation of functional cell region 206D(2) and thus functional cell region 206D(1) is considered a minor variation of the first arrangement of components.

In macro region 202D of FIG. 2D, relative to the X-axis, each of a left boundary and a right boundary of functional cell regions 206D(1)-206D(2) and 208D(1) corresponds to an isolation dummy gate (IDG) rather than corresponding gate segments. In some embodiments, an isolation dummy gate is a dielectric structure that includes one or more dielectric materials and functions as an electrical isolation structure. Accordingly, an isolation dummy gate is not a structure that is electrically conductive and thus does not function, e.g., as an active gate of a transistor. An isolation dummy gate includes one or more dielectric materials and functions as an electrical isolation structure. In some embodiments, an isolation dummy gate is based on a gate structure as a precursor. In some embodiments, a dummy gate structure includes a gate conductor, a gate-insulator layer, (optionally) one or more spacers, or the like. In some embodiments, an isolation dummy gate is formed by first forming a gate structure, e.g., a dummy gate structure, sacrificing/removing (e.g., etching) the gate conductor of the gate structure to form a trench, (optionally) removing a portion of a substrate that previously had been under the gate conductor to deepen the trench, and then filling the trench with one or more dielectric materials such that the physical dimensions of the resultant electrical isolation structure, i.e., the isolation dummy gate, are similar to the dimensions of the dummy gate conductor which was sacrificed, namely the gate conductor or the combination of the gate conductor and the portion of the substrate. In some embodiments, an isolation dummy gate is a dielectric feature that includes one or more dielectric materials (e.g., oxide, nitride, oxynitride, or other suitable materials), and functions as an isolation feature. In some embodiments, an isolation dummy gate is a continuous polysilicon on oxide diffusion (OD) edge structure, and is referred to as a CPODE structure.

In FIG. 2D, boundaries of each of functional cell regions 206D(1)-206D(2) and 208D(1) are identifiable in a corresponding device by one or more features including the following. In some embodiments, a top boundary of each of functional cell regions 206D(1)-206D(2) and 208D(1) is defined by a first reference line which extends parallel to the X-axis and is proximate and parallel to a line intersecting upper ends of a first majority of the gate segments, e.g., all in the example of FIG. 2D. In some embodiments, a bottom boundary of each of functional cell regions 206D(1)-206D(2) and 208D(1) is defined by a second reference line which extends parallel to the X-axis and is proximate and parallel to a line intersecting a second majority of the gate segments, e.g., all in the example of FIG. 2D. In some embodiments, e.g., as in FIG. 2D, left and right boundaries of each of functional cell regions 206D(1)-206D(2) and 208D(1) are defined by corresponding portions of the IDGs. In some embodiments, a left boundary of each of functional cell regions 206D(1)-206D(2) and 208D(1) is defined by a third reference line which extends parallel to the Y-axis and is proximate and parallel to a line intersecting left ends of a first majority of the M0_rte segments, e.g., all in the example of FIG. 2D; and a right boundary of each of functional cell regions 206D(1)-206D(2) and 208D(1) is defined by a fourth reference line which extends parallel to the Y-axis and is proximate and parallel to a line intersecting right ends of a second majority of the M0_rte segments, e.g., all in the example of FIG. 2D. In some embodiments, boundaries of cell regions are identified by dummy source/drain regions, and/or dummy conductors. In some embodiments, boundaries of cell regions are identified by power rails (e.g., VDD rails or ground rails). In some embodiments, boundaries of cell regions are identified by finding locations that do not include certain types of interconnects. In some embodiments, boundaries are identified by empty space or dummy regions.

Relative to the Y-axis, the bottom boundary of functional cell region 208D(1) is also the top boundary of functional cell region 206D(2). In FIG. 2D: the top alpha track of functional cell region 208D(1) is assumed to be alpha track α6; the bottom alpha track of functional cell region 208D(1) is assumed to be alpha track α10; the top alpha track of functional cell region 206D(2) is assumed to be alpha track α11; and the bottom alpha track of functional cell region 206D(2) is assumed to be alpha track α15.

In FIG. 2D, relative to the X-axis, the gate segments are separated from each other by a uniform distance/pitch, p_gate. A value for pitch p_gate depends on the corresponding semiconductor process technology node. In some embodiments, pitch p_gate represents one contacted poly pitch (CPP) for the corresponding semiconductor process technology node. Here, the word ‘poly’ in the term CPP does not necessarily imply that the gate structures in semiconductor devices based correspondingly on FIG. 2D, or the like, are to be formed of polysilicon but instead represents a historical convenience, i.e., because gate structures in ICs manufactured according to a predecessor semiconductor process technology node often were formed of polysilicon.

In FIG. 2D, relative to the Y-axis, the M0_rte segments are separated from each other by a uniform distance/pitch, p_M0_rte. A value for pitch p_M0_rte depends on the corresponding semiconductor process technology node. In FIG. 2D, as well as in other layout diagrams disclosed herein, M0_rte segments which are aligned to a same one of the alpha tracks are referred to as alpha-coaligned M0_rte segments.

In FIG. 2D, as well as in other layout diagrams disclosed herein, VG contacts which are aligned to a same one of the beta tracks are referred to as beta-coaligned VG contacts. Relative to the Y-axis, adjacent ones of beta-coaligned VG contacts are separated by a minimum distance, gap_VG. In some embodiments, gap_VG is approximately equal to, or greater than, a lesser of p_gate or twice p_M0_rte such that min{≈(p_gate), ≈(2*p_M0_rte)≤gap_VG. According to another approach for producing a device having a BSPD architecture, a counterpart minimum distance (OA_gap_VG) between adjacent beta-coaligned counterpart VG contacts is approximately equal to a counterpart M0_rte pitch (OA_p_M0_rte). The counterpart gap OA_gap_VG is so small that the other approach requires the use of two EUVL masks to manufacture adjacent beta-coaligned counterpart VG contacts of a corresponding device, where EUVL is an acronym for Extreme Ultraviolet Lithography. By contrast, due at least in part to one or more of the design rules disclosed herein, at least some embodiments use a relatively larger minimum distance between adjacent beta-coaligned VG contacts, namely gap_VG, for which one EUVL mask is sufficient to manufacture adjacent beta-coaligned VG contacts of a corresponding device; accordingly, by eliminating one EUVL mask, such embodiments at least are less expensive and/or faster to manufacture as compared to the other approach.

In FIG. 2D, as well as in other layout diagrams disclosed herein, VD contacts which are aligned to a same one of the beta tracks are referred to as beta-coaligned VD contacts. Relative to the Y-axis, adjacent ones of beta-coaligned VD contacts are separated by a minimum distance, gap_VD. In some embodiments, gap_VD is approximately equal to, or greater than, a lesser of p_gate or twice p_M0_rte such that min{≈(p_gate), ≈(2*p_M0_rte)≤gap_VD. According to another approach for producing a device having a BSPD architecture, a counterpart minimum distance (OA_gap_VD) between adjacent beta-coaligned counterpart VD contacts is approximately equal to the counterpart M0_rte pitch (OA_p_M0_rte). The counterpart gap OA_gap_VD is so small that the other approach requires the use of two EUVL masks to manufacture adjacent beta-coaligned counterpart VD contacts of a corresponding device. By contrast, due at least in part to one or more of the design rules disclosed herein, at least some embodiments use a relatively larger minimum distance between adjacent beta-coaligned VD contacts, namely gap_VD, for which one EUVL mask is sufficient to manufacture adjacent beta-coaligned VD contacts of a corresponding device; accordingly, by eliminating one EUVL mask, such embodiments at least are less expensive and/or faster to manufacture as compared to the other approach.

In FIG. 2D, as well as in other layout diagrams disclosed herein, V0 structures which are aligned to a same one of the beta tracks are referred to as beta-coaligned V0 structures. Relative to the Y-axis, adjacent ones of beta-coaligned V0 structures are separated by a minimum distance, gap_V0. In some embodiments, gap_V0 is approximately equal to, or greater than, a lesser of p_gate or twice p_M0_rte such that min{≈(p_gate), ≈(2*p_M0_rte)≤gap_V0. According to another approach for producing a device having a BSPD architecture, a counterpart minimum distance (OA_gap_V0) between adjacent beta-coaligned counterpart V0 structures is approximately equal to the counterpart M0_rte pitch (OA_p_M0_rte). The counterpart gap OA_gap_V0 is so small that the other approach requires the use of two EUVL masks to manufacture adjacent beta-coaligned counterpart V0 structures of a corresponding device. By contrast, due at least in part to one or more of the design rules disclosed herein, at least some embodiments use a relatively larger minimum distance between adjacent beta-coaligned V0 structures, namely gap_V0, for which one EUVL mask is sufficient to manufacture adjacent beta-coaligned V0 structures of a corresponding device; accordingly, by eliminating one EUVL mask, such embodiments at least are less expensive and/or faster to manufacture as compared to the other approach.

In FIG. 2D, as well as in other layout diagrams disclosed herein, M1_rte segments which are aligned to a same one of the beta tracks are referred to as beta-coaligned M1_rte segments. Relative to the Y-axis, adjacent ends of beta-coaligned M1_rte segments are separated by a minimum distance, gap_M1_E2E. In some embodiments, gap_M1_E2E is substantially greater than p_M0_rte. In some embodiments, gap_M1_E2E is about twice as large as p_M0_rte such that ≈(2*p_M0_rte)≤gap_M1_E2E. According to another approach for producing a device having a BSPD architecture, a counterpart minimum distance (OA_gap_M1_E2E) between adjacent ends of beta-coaligned counterpart M1_rte segments is approximately equal to a counterpart minimum distance (OA_gap_M0) between adjacent counterpart M0_rte segments, relative to the Y-axis. In general, regarding segments in a metallization layer, as end-to-end (E2E) distances decrease, the difficulty of dividing/cutting a longer precursor segment into two parts having adjacent ends separated by a corresponding minimum E2E distance increases. due at least in part to one or more of the design rules disclosed herein, at least some embodiments use a minimum distance between adjacent ends of beta-coaligned M1_rte segments, namely gap_M1_E2E, to manufacture adjacent ends of beta-coaligned M1_rte segments, where gap_M1_E2E is substantially greater than the counterpart minimum distance OA_gap_M1_E2E; accordingly, it is at least easier and/or less expensive to manufacture adjacent ends of beta-coaligned M1_rte segments as compared to the other approach.

In FIG. 2D, and in other layout diagrams disclosed herein, and relative to the Y-axis, each functional cell region (e.g., 206D(1) in FIG. 2D) is assumed to have a height equal to six alpha tracks such that each functional cell region overlaps five alpha tracks (e.g., α1-α5 in FIG. 2D), i.e., five rows of M0_rte segments. In some embodiments, functional cell regions have a height equal to or greater than four alpha tracks such that each function cell region overlaps at least three alpha tracks.

Assuming a substantially same pitch for alpha tracks, according to another approach for producing a device having a BSPD architecture, a counterpart functional cell region having a height equal to six alpha tracks overlaps only four rows of counterpart M0_rte segments. due at least in part to one or more of the design rules disclosed herein, in some embodiments, a functional cell region having a height equal to six alpha tracks overlaps five rows of M0_rte segments which achieves one extra row of M0_rte segments as compared to the other approach. In some embodiments, regarding a gate density of transistors formed in a given functional cell region, the functional cell region having a height equal to six alpha tracks and overlapping five rows of M0_rte segments achieves a gate density, G_dens, in a range (≈1.04)≤G_dens≤(≈1.06) as compared to the counterpart functional cell region having a height equal to six alpha tracks and overlapping only four rows of M0_rte segments according to the other approach, an improvement in range of about 4% to about 6%.

Differences between the first and second arrangements of FIG. 2D include the following. Regarding a reference line 214(1) that extends parallel to the X-axis, all the VD contacts and half of the VG contacts in functional cell regions 208D(1) and 206D(2) exhibit mirror symmetry with respect to reference line 214(1). Exceptions to the VG/VD mirror symmetry between functional cell regions 208D(1) and 206D(2) include: the location of the VG contact at the intersection of alpha track α10 and beta track β7 in functional cell region 208D(1) and the location of the VG contact at the intersection of alpha track α12 and beta track β7 in functional cell region 206D(2); and the location of the VG contact at the intersection of alpha track α9 and beta track β9 in functional cell region 208D(1) and the location of the VG contact at the intersection of alpha track α14 and beta track β9 in functional cell region 206D(2). Regarding a reference line 214(2) that extends parallel to the X-axis, the V0 structures and the M1_rte segments exhibit mirror symmetry with respect to reference line 214(2).

Differences between the first and second arrangements of FIG. 2D further include the following. Relative locations in functional cell regions 208D(1) and 206D(2) are relative to a context of the top and bottom boundaries correspondingly of functional cell regions 208D(1) and 206D(2). While two alpha tracks in each of functional cell regions 208D(1) and 206D(2) have alpha-coaligned M0_rte segments, the relative locations of the two alpha tracks (α7 and α9) in functional cell region 208D(1) is different than the relative locations of the two alpha tracks (α12 and α13) in functional cell region 206D(2). While each of the gap between alpha-coaligned M0_rte segments of alpha track α7 in functional cell region 208D(1) and the gap between alpha-coaligned M0_rte segments of alpha track α13 in functional cell region 206D(2) is aligned to beta track β5, the gap between alpha-coaligned M0_rte segments of alpha track α9 in functional cell region 208D(1) is aligned to beta track β8 whereas the gap between alpha-coaligned M0_rte segments of alpha track α12 in functional cell region 206D(2) is aligned to beta track β6.

FIG. 2E is a layout diagram of a macro region 202E, in accordance with some embodiments.

Macro region 202E is a version of macro region 202D. Macro region 202E is an example of macro region 102 of FIG. 1. In FIG. 2E, section line 4B-4B′ extends parallel to the X-axis. In some embodiments, section line 4B-4B′ of FIG. 2E corresponds to cross-section 420B of FIG. 4B.

Comparing macro region 202E to macro region 202D, macro region 202E does not include the active regions (ARs), the V0 structures nor the M1_rte segments, for simplicity of illustration. By contrast, comparing macro region 202E to macro region 202D, macro region 202E further includes cut-gate-segment (CG) shapes and cut-MD-contact (CMD) shapes.

In FIG. 2E, as well as in other layout diagrams disclosed herein, gate segments which are aligned to a same one of the beta tracks are referred to as beta-coaligned gate segments. Adjacent beta-coaligned gate segments are the result of dividing/cutting a longer precursor segment into two parts having adjacent ends separated by a corresponding minimum distance; CG shapes are used to indicate where a longer precursor segment (not shown) would have been divided/cut.

Relative to the Y-axis, adjacent ends of beta-coaligned gate segments are separated by a minimum distance, h_CG, where h_CG also represents a height of the CG shape. In some embodiments, h_CG is approximately equal to p_M0_rte such that h_CG≈p_M0_rte. According to another approach for producing a device having a BSPD architecture, a counterpart minimum distance (OA_h_CG) between adjacent ends of beta-coaligned counterpart gate segments is approximately equal to the counterpart minimum distance (OA_gap_M0) between adjacent counterpart M0_rte segments, relative to the Y-axis. In general, regarding segments in a metallization layer, as end-to-end (E2E) distances decrease, the difficulty of dividing/cutting a longer precursor segment into two parts having adjacent ends separated by a corresponding minimum E2E distance increases. At least some embodiments use a minimum distance between adjacent ends of beta-coaligned gate segments, namely h_CG, to manufacture adjacent ends of beta-coaligned gate segments, where h_CG is substantially greater than the counterpart minimum distance OA_h_CG; accordingly, it is at least easier and/or less expensive to manufacture adjacent ends of beta-coaligned gate segments as compared to the other approach.

In FIG. 2E, as well as in other layout diagrams disclosed herein, MD contacts which are aligned to a same one of the beta tracks are referred to as beta-coaligned beta-coaligned MD contacts. Adjacent beta-coaligned MD contacts are the result of dividing/cutting a longer precursor contact into two parts having adjacent ends separated by a corresponding minimum distance; CMD shapes are used to indicate where a longer precursor contact (not shown) would have been divided/cut.

Relative to the Y-axis, adjacent ends of beta-coaligned MD contacts are separated by a minimum distance, h_CMD, where h_CMD also represents a height of the CMD shape. In some embodiments, h_CMD is approximately equal to p_M0_rte such that h_CMD≈p_M0_rte. According to another approach for producing a device having a BSPD architecture, a counterpart minimum distance (OA_h_CMD) between adjacent ends of beta-coaligned counterpart MD contacts is approximately equal to the counterpart minimum distance (OA_gap_M0) between adjacent counterpart M0_rte segments, relative to the Y-axis. In general, regarding segments in a metallization layer, as end-to-end (E2E) distances decrease, the difficulty of dividing/cutting a longer precursor segment into two parts having adjacent ends separated by a corresponding minimum E2E distance increases. At least some embodiments use a minimum distance between adjacent ends of beta-coaligned MD contacts, namely h_CMD, to manufacture adjacent ends of beta-coaligned MD contacts, where h_CMD is substantially greater than the counterpart minimum distance OA_h_CMD; accordingly, it is at least easier and/or less expensive to manufacture adjacent ends of beta-coaligned MD contacts as compared to the other approach.

In FIG. 2E, macro region is a representation of third and fourth design rules (DRs) that result in macro region 202D of FIG. 2D, as discussed below.

Regarding FIG. 2E, the third design rule relates to the first alpha track of each of functional cell regions 206D(1)-206D(2) and 208D(1). In the context of functional cell regions 206D(1)-206D(2) and 208D(1), the first alpha tracks are referred to as the bottom alpha tracks. In functional cell regions 206D(1)-206D(2) and 208D(1), the bottom alpha tracks are assumed to be alpha track α5, α10 and α15. The third design rule specifies that the bottom alpha track is to be free of having any CMD shape aligned thereto. In some embodiments, the third design rule is referred to as a CMD-non-grata-track design rule.

Regarding FIG. 2E, the fourth design rule relates to the second alpha track of each of functional cell regions 206D(1)-206D(2) and 208D(1)-208(2). In the context of functional cell regions 206D(1)-206D(2) and 208D(1), the second alpha tracks are referred to as the top alpha tracks. In functional cell regions 206D(1)-206D(2) and 208D(1)-208(2), the top alpha track are assumed to be alpha track α1, α6 and α11. The fourth design rule specifies that the top alpha track is to be free of having any CG shape aligned thereto. In some embodiments, the fourth design rule is referred to as a CG-non-grata-track design rule.

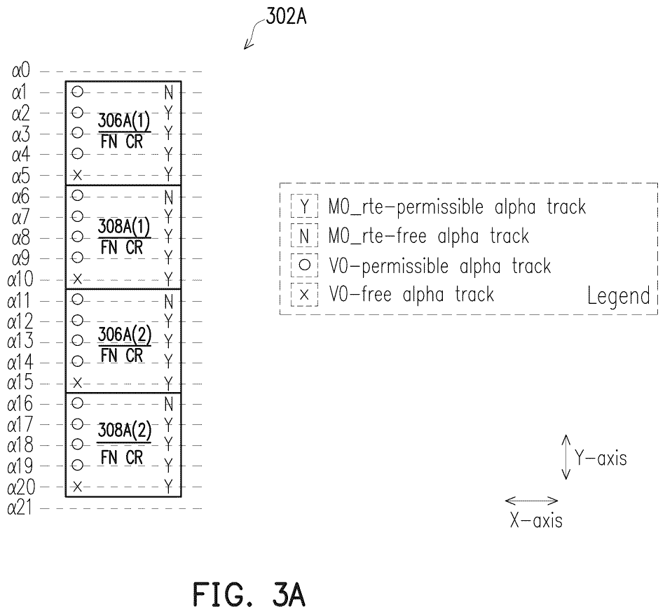

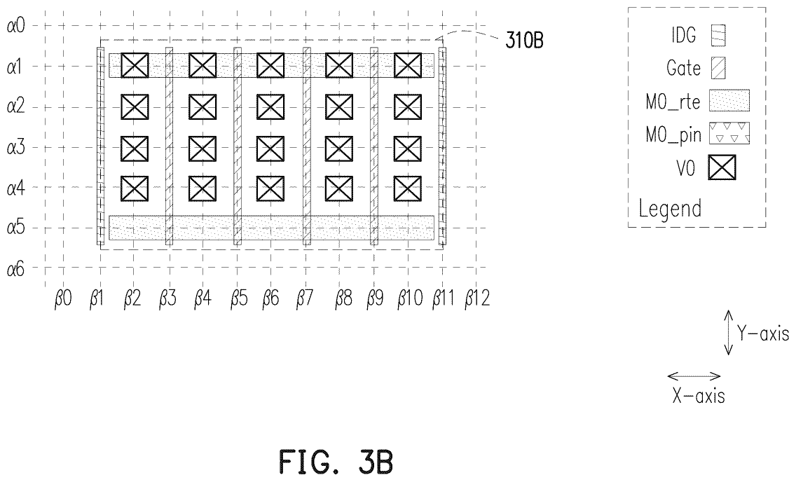

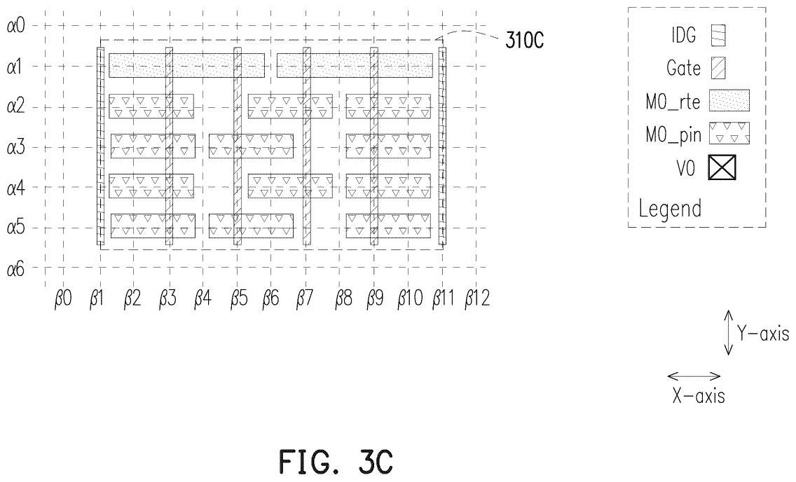

FIG. 3A is a layout diagram of a macro region 302A, in accordance with some embodiments.

Macro region 302A is an example of macro region 102 of FIG. 1.

Macro region 302A includes functional (FN) cell regions 306A(1)-306A(2) and 308A(1)-308A(2) which are stacked relative to the Y-axis. Functional cell region 306A(2) is stacked on functional cell region 308A(2). Functional cell region 308A(1) is stacked on functional cell region 306A(2). Functional cell region 306A(1) is stacked on functional cell region 308A(1). Functional cell regions 306A(1)-306A(2) and 308A(1)-308A(2) are also described as being interleaved relative to the Y-axis.

Each of functional cell regions 306A(1)-306A(2) and 308A(1)-308A(2) is configured to perform a given function, e.g., AOI (see, e.g., FIG. 5A). That is, each of functional cell regions 306A(1)-306A(2) and 308A(1)-308A(2) is configured to perform the same function.

The components (see, e.g., FIGS. 3B-3C) included in each of functional cell regions 306A(1)-306A(2) and 308A(1)-308A(2) include: gate segments (see, e.g., FIGS. 3B-3C); MD contacts (see, e.g., FIGS. 2B and 2E); VG contacts (see, e.g., FIGS. 2C-2E); VD contacts (see, e.g., FIGS. 2B and 2D-2E); M0_rte segments; ones of the M0_rte segments that are input/output (pin) M0 segments (M0_pin segments); and V0 structures. In FIG. 3A, and in the other figures disclosed herein, the V0 structures are aligned to corresponding ones of the alpha track lines and the beta track lines.

Functional cell regions 306A(1)-306A(2) are instances of a third arrangement of components that is configured to perform the given function. Functional cell regions 308A(1)-306A(2) are instances of a fourth arrangement of components that is configured to perform the given function.

In some embodiments, the third and fourth arrangements refer to corresponding arrangements of the gate segments, MD contacts, V0 contacts and M0_pin segments. In some embodiments, the third and fourth arrangements refer to corresponding arrangements of the gate segments, MD contacts, V0 contacts and M0_pin segments, plus non-pin M0_rte segments.

Examples of differences between the third and fourth arrangements are discussed below. Despite the third and fourth arrangements being different, nevertheless, the third and fourth arrangements have properties in common. A first property common to the third and fourth arrangements is that the VD structures are aligned to corresponding even ones of the beta track lines (e.g., beta track lines β2-β10 of FIGS. 3D-3E). A second property common to the third and fourth arrangements is shown in FIGS. 3B-3C.

FIGS. 3B-3C are layout diagrams of corresponding functional cell region 310B-310C, in accordance with some embodiments.

Regarding FIGS. 3B-3C, each of functional cell regions 310B and 310C is an example of functional cell regions 306A(1)-306A(2) and 308A(1)-308A(2) of FIG. 3A. Functional cell regions 310B-310C are representations of corresponding fifth and sixth design rules (DRs) that result in the third and fourth arrangements of FIG. 3A, as discussed below.

Regarding FIGS. 3A-3B, the fifth design rule relates to the first alpha track of each of functional cell regions 306D(1)-306D(2) and 308D(1)-308D(2) of FIG. 3A and 310B of FIG. 3B. In the context of functional cell regions 306D(1)-306D(2) and 308D(1)-308D(2) of FIG. 3A and 310B of FIG. 3B, the first alpha tracks are referred to as the bottom alpha tracks. In functional cell regions 306D(1)-306D(2) and 308D(1)-308D(2) of FIG. 3A and 310B of FIG. 3B, the bottom alpha tracks are assumed to be alpha tracks α5, α10, α15 α20. The fifth design rule specifies that the bottom alpha track is to be free of having any V0 structure aligned thereto. In some embodiments, the fifth design rule is referred to as a V0-structure-non-grata-track design rule.

Regarding FIGS. 3A and 3C, the sixth design rule relates to the second alpha track of each of functional cell regions 306D(1)-306D(2) and 308D(1)-308D(2) of FIG. 3A and 310C of FIG. 3C. In the context of functional cell regions 306D(1)-306D(2) and 308D(1)-308D(2) of FIG. 3A and 310C of FIG. 3C, the second alpha tracks are referred to as the top alpha tracks. In functional cell regions tracks 306D(1)-306D(2) and 308D(1)-308D(2) of FIG. 3A and 310C of FIG. 3C, the top alpha tracks are assumed to be alpha tracks α1, α6, α11 and α16. The sixth design rule specifies that the top alpha track is to be free of having any M0_pin segments aligned thereto. In some embodiments, the sixth design rule is referred to as a M0_pin-non-grata-track design rule.

In functional cell regions 306D(1)-306D(2) and 308D(1)-308D(2) of FIG. 3A and 310C of FIG. 3C and 310B of FIG. 3B, V0 structures are permissible in the top alpha track and in each of the interior alpha tracks that is between the top alpha track and the bottom alpha track. For example, the interior alpha tracks are alpha tracks α2-α4 in each of FIGS. 3B-3C. In other words, in functional cell regions 306D(1)-306D(2) and 308D(1)-308D(2) of FIG. 3A and 310C of FIG. 3C and 310B of FIG. 3B, each of alpha tracks α1-α4 is a V0-permissible alpha track.

In functional cell region 306D(1)-306D(2) and 308D(1)-308D(2) of FIG. 3A and 310C of FIG. 3C and 310C of FIG. 3C, M0_pin segments are permissible in the bottom alpha track and in each of the interior alpha tracks. In other words, in functional cell regions 306D(1)-306D(2) and 308D(1)-308D(2) of FIG. 3A and 310C of FIG. 3C and 310C of FIG. 3C, each of alpha tracks α2-α5 is an M0_pin-permissible alpha track.

The second property common to the third and fourth arrangements, mentioned above in the discussion of FIG. 3A, is shown (again) in FIGS. 3B-3C.

In each of functional cell regions 310B and 310C, V0 structures are permissible in each of the interior alpha tracks, namely alpha tracks α2-α4 in each of FIGS. 3B-3C. In each of functional cell regions 310B and 310C, M0_pin segments are permissible in each of the interior alpha tracks, namely (again) alpha tracks α2-α4 in each of FIGS. 3B-3C. Hence, the third property common to the third and fourth arrangements is that V0 structures and/or M0_pin segments are permissible in each of alpha tracks α2-α4 in each of FIGS. 3B-3C. In other words, as shown in FIGS. 3B-3C, the third property common to the third and fourth arrangements is that each of alpha tracks α2-α4 is a V0-permissible alpha track and an M0_pin-permissible alpha track.

FIGS. 4A-4B are corresponding cross-sections 420A-420B of a portion of a device, in accordance with some embodiments.

In some embodiments, the portion of the device of FIGS. 4A-4B is an example of a portion of a device based on the layout diagrams of FIGS. 2D-2E. The device of FIGS. 4A-4B is an example of device 100 of FIG. 1. In some embodiments, cross-section 420A corresponds to section line 4A-4A′ of FIG. 2D. In some embodiments, cross-section 420B corresponds to section line 4B-4B′ of FIG. 2E.

FIG. 5A is a collection of three layout diagrams, in accordance with some embodiments. FIGS. 5B-5C are corresponding simple block diagrams, in accordance with some embodiments.

FIG. 5A includes functional cell regions 506 and 508 and an intermediate cell region 516. FIG. 5B represents spatial rearrangement in intermediate cell 516 as compared to functional cell region 506. FIG. 5C represents spatial rearrangement in functional cell region 508 as compared to intermediate cell 516.

Each of functional cell regions 506 and 508 is configured to perform a given function. In the example of FIG. 5A, each of functional cell regions 506 and 508 is configured to perform the logical function of AND-OR-INVERT (AOI). That is, each of functional cell regions 506 and 508 208A(2) is configured to perform the same function, namely AOI.

In some embodiments, each of functional cell regions 506 and 508 is configured as an AOI22D1 cell region. In some embodiments, AOI22DX is an alphanumeric text string intended to connote that the corresponding cell region is an AOI cell region for which the driving strength of the cell region is DX, where X is a multiple of a unit driving strength D. In FIG. 5A, X is assumed to be one such that X=1.

Functional cell regions 506 is an instance of a first arrangement of components that is configured to perform the AOI function. Functional cell region 508 is an instance of a second arrangement of components that is configured to perform the AOI function. The first and second arrangements facilitate interleaved/interspersed stacking of the same, relative to the Y-axis.

Regarding FIG. 5B, it is to be recalled that FIG. 5B represents spatial rearrangement in intermediate cell 516 as compared to functional cell region 506. An axis of symmetry is represented by a reference line 214(3) that extends parallel to X-axis. Reference line 214(3) is substantially halfway between alpha tracks α3 and α4, relative to the Y-axis. In light of the character p representing the Greek letter rho, rows ρ0-ρ4 of functional cell region 506 are rotated about reference line 214(3) resulting in rows ρ0′-ρ4′ of intermediate cell region 516.

Regarding FIG. 5C, it is to be recalled that FIG. 5C represents spatial rearrangement in functional cell region 508 as compared to intermediate cell 516. The VG contact at the intersection of row ρ4′ and beta track β7 is shifted to the intersection of row ρ2′ and beta track β7. The gap between alpha-coaligned M0_rte segments in row ρ3′ (between beta tracks β7 and β9) is moved the intersection of row ρ2′ and beta track β6. Row ρ4′ is shifted from being collinear with alpha track α0 to its original position collinear with alpha track α6 to form row ρ4″. The VG contact at the intersection of row ρ3′ and beta track β9 is shifted to the intersection of row ρ4″ and beta track β9.

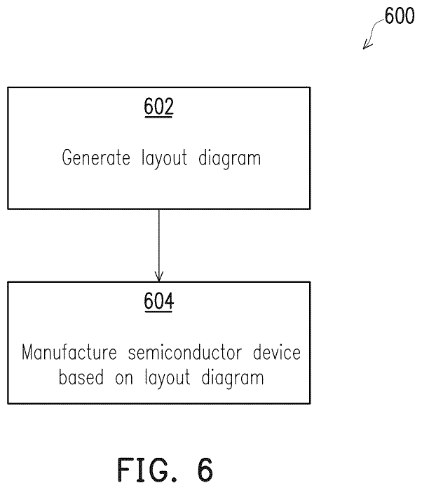

FIG. 6 is a flowchart (flow diagram) of a method 600A of manufacturing a system or device, in accordance with some embodiments.

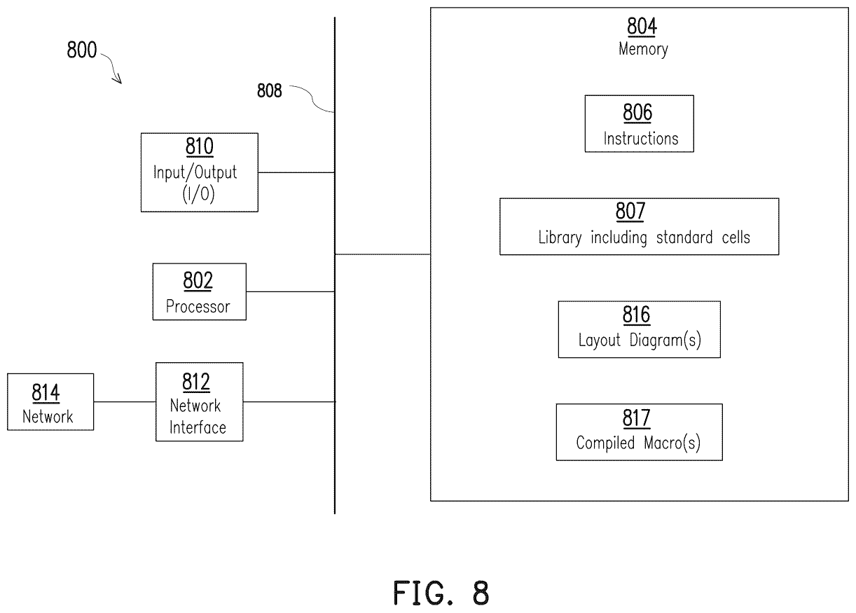

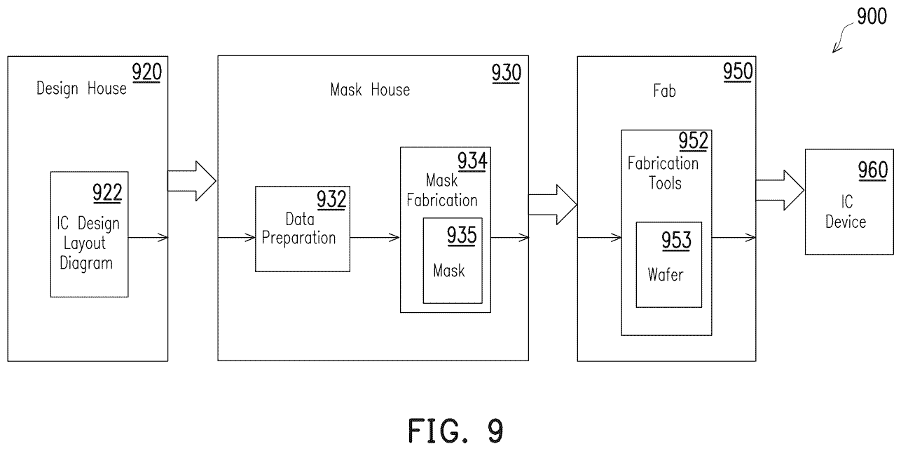

Method 600 is implementable, for example, using EDA system 800 (FIG. 8, discussed below) and an IC manufacturing system 900 (FIG. 9, discussed below), in accordance with some embodiments. Examples of system or device that includes a functional cell region which can be manufactured according to method 600A include systems or devices that include the functional cell regions disclosed herein, or the like.

In FIG. 6, method 600 includes blocks 602-604. At block 602, a layout diagram is generated which, among other things, includes one or more layout diagrams corresponding to one or more of the functional cell regions disclosed herein, one or more of the macro cell regions disclosed herein, or the like. Block 602 is implementable, for example, using EDA system 800 (FIG. 8, discussed below), in accordance with some embodiments. From block 602, flow proceeds to block 604.

At block 604, based on the layout diagram, at least one of (A) one or more photolithographic exposures are made or (b) one or more photolithography masks are fabricated or (C) one or more components in a layer of a device, e.g., a device is fabricated. See discussion below of IC manufacturing system 900 in FIG. 9 below.

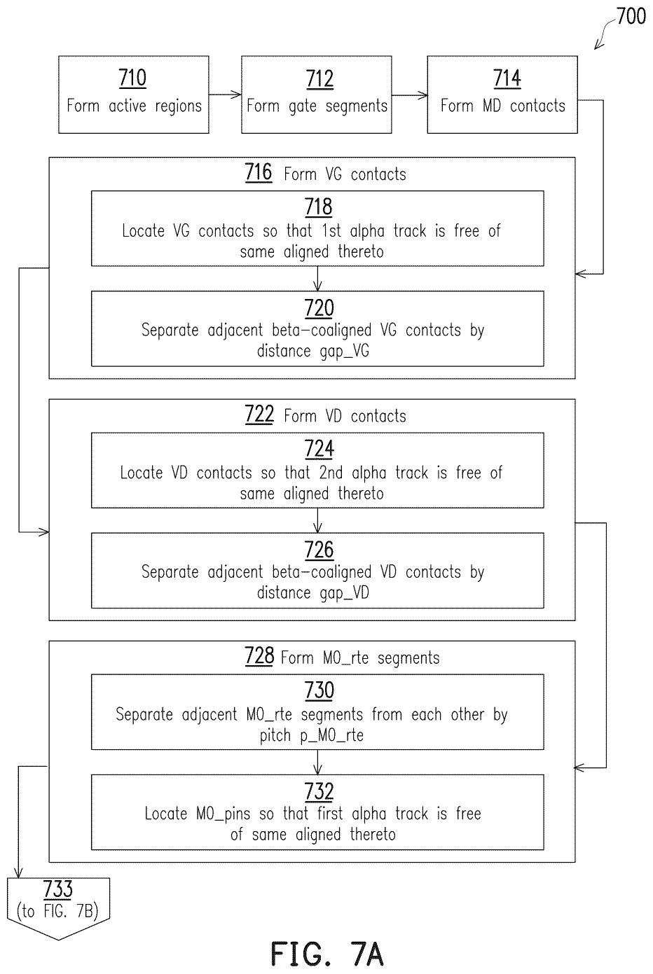

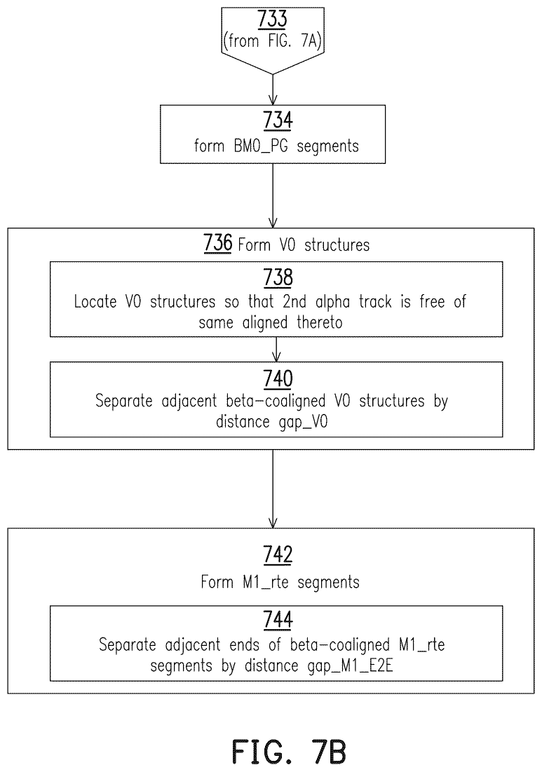

FIGS. 7A-7B are corresponding parts of a flowchart of a method 700 of manufacturing a device, in accordance with some embodiments.

Method 700 is an example of block 604 (see FIG. 6, discussed above). Method 700 is implementable, for example, using IC manufacturing system 900 (see FIG. 9, discussed below), in accordance with some embodiments. Examples of a devices which can be manufactured according to method 700 include devices that one or more of the functional cell regions disclosed herein, one or more of the macro cell regions disclosed herein, or the like. Method 700 includes blocks 710-744.

At block 710, active regions active regions (e.g., see FIGS. 2D & 4A-4B) are formed extending in a first direction (e.g., parallel to the X-axis). From block 710, flow proceeds to block 712.

At block 712, gate segments (e.g., see FIGS. 2A-2E & 4A-4B) are formed which extend in a second direction (e.g., parallel to the Y-axis) perpendicular to the first direction, are interspersed, and have portions over areas of the active regions. From block 712, flow proceeds to block 714.

At block 714, MD contacts (e.g., see FIGS. 2E & 4A-4B) are formed which extend in the second direction, are interspersed, and have portions over areas of the active regions. From block 714, flow proceeds to block 716.

At block 716, VG contacts (e.g., see FIGS. 2C-2E & 4A-4B) are formed over areas of the gate segments. Block 716 includes blocks 718-720. Within block 716, flow proceeds to block 718.

At block 718, VG contacts are located to be aligned to corresponding ones of the alpha tracks with the exception that the first alpha track (e.g., see, alpha tracks α1, α6, α11 and α16 correspondingly of FIGS. 2A-2C) is free of having any VG contact aligned thereto. From block 718, flow proceeds to block 720.

At block 720, adjacent beta-coaligned VG contacts are spaced apart to be separated by a distance gap_VG (e.g., see FIG. 2D). From block 720, flow exits block 716 and proceeds to block 722.

At block 722, VD contacts (e.g., see FIGS. 2C-2E & 4A-4B) are formed over areas of the MD contacts. Block 722 includes blocks 724-726. Within block 722, flow proceeds to block 724.

At block 724, VD contacts are located to be aligned to corresponding ones of the alpha tracks with the exception that the last alpha track (e.g., see, alpha tracks α5, α10, α15 and α20 correspondingly of FIGS. 2A-2E) is free of having any VD contact aligned thereto. From block 724, flow proceeds to block 726.

At block 726, adjacent beta-coaligned VD contacts are spaced apart to be separated by a distance gap_VD (e.g., see FIG. 2D). From block 726, flow exits block 722 and proceeds to block 728.

At block 728, in a first layer of metallization (e.g., see MET0 of FIGS. 4A-4B), M0_rte segments (e.g., see FIGS. 2B-2E, 3B-3C & 4A-4B) are formed which extend in the first direction(e.g., parallel to the X-axis), are aligned correspondingly to the alpha tracks (e.g., see α0, α1, . . . ) , and are correspondingly over the VG contacts or the VD contacts. Block 728 includes blocks 730-732. Within block 728, flow proceeds to block 730.

At block 730, relative to the Y-axis, adjacent M0_rte segments are spaced apart to be separated from each other by pitch p_M_rte (e.g., see FIG. 2D). From block 730, flow proceeds to block 732.

At block 732, M0_pins, i.e., pin ones of the M0_rte segments, are located to be aligned to corresponding ones of the alpha tracks with the exception that the first alpha track (e.g., see, alpha track α1 of FIG. 3C) is free of having any M0_pin segment contact aligned thereto. From block 732, flow exits block 728 and proceeds to off-page connector block 733. From off-page connector block 733 in FIG. 7A, flow proceeds to off-page connector block 733 in FIG. 7B.

In FIG. 7B, flow proceeds from off-page connector block 733 to block 734.

At block 734, in a first buried layer of metallization (e.g., see BMET0 of FIGS. 4A-4B), BM0_PG segments (e.g., see FIGS. 2D-2E & 4A-4B) are formed which extend in the first direction(e.g., parallel to the X-axis). From block 734, flow proceeds to block 736.

At block 736, V0 structures (e.g., see FIGS. 2D, 3B & 4A) are formed over areas of the M0_rte segments and aligned to corresponding ones of the beta tracks (e.g., see β4). Block 736 includes blocks 738-740. Within block 736, flow proceeds to block 738.

At block 738, V0 structures are located to be aligned to corresponding ones of the alpha tracks with the exception that the last alpha track (e.g., see, alpha tracks α5, α10, α15 and α20 correspondingly of FIGS. 2D, 3A-3C) is free of having any V0 structure aligned thereto. From block 738, flow proceeds to block 740.

At block 740, adjacent beta-coaligned V0 structures are spaced apart to be separated by a distance gap_V0 (e.g., see FIG. 2D). From block 740, flow exits block 736 and proceeds to block 742.

At block 742, in a second layer of metallization (e.g., see MET1 of FIGS. 4A-4B), M1_rte segments (e.g., see FIGS. 2D & 4A) are formed which extend in the second direction (e.g., parallel to the Y-axis), are aligned correspondingly to the beta tracks (e.g., see β4), and are correspondingly over the V0 structures. Block 742 includes block 744. Within block 742, flow proceeds to block 744.

At block 744, relative to the Y-axis, adjacent ends of M1_rte segments are spaced apart to be separated from each other by a distance gap_M1_E2E (e.g., see FIG. 2D).

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a processor 802 (e.g., a hardware processor) and a non-transitory, computer-readable storage medium 804. Storage medium 804, amongst other things, is encoded with, i.e., stores, computer program code 806, i.e., a set of executable instructions. Execution of instructions 806 by processor 802 represents (at least in part) an EDA tool which implements a portion of or all, e.g., one or more methods of generating layout diagrams corresponding to the layout diagrams disclosed herein, or the like, in accordance with one or more embodiments (hereinafter, the noted processes and/or methods).

Storage medium 804, amongst other things, stores layout diagrams 811 such as the layout diagrams disclosed herein, other the like.

Processor 802 is electrically coupled to storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and storage medium 804 are capable of connecting to external elements via network 814. Processor 802 is configured to execute computer program code 806 encoded in storage medium 804 in order to cause EDA system 800 to be usable for performing a portion of or all the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, storage medium 804 is an electronic, magnetic, optical, electromagnetic, infrared, and/or a semiconductor system (or apparatus or device). For example, storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, storage medium 804 includes a compact disk-read only memory (CD-ROM), a compact disk-read/write (CD-R/W), and/or a digital video disc (DVD).

In one or more embodiments, storage medium 804 stores instructions, i.e., computer program code 806 configured to cause EDA system 800 (where such execution represents (at least in part) the EDA tool) to be usable for performing a portion of or all the noted processes and/or methods. In one or more embodiments, storage medium 804 further stores information which facilitates performing a portion of or all the noted processes and/or methods. In one or more embodiments, storage medium 804 stores library 807 of standard cells including standard cells that correspond to components of the layout diagrams disclosed herein. Storage medium 804 stores one or more layout diagrams 816 such as one or more layout diagrams corresponding to the layout diagrams disclosed herein, one or more compiled macros 817 based on layout diagrams including one or more of the layout diagrams disclosed herein, or the like.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows EDA system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion of or all noted processes and/or methods, is implemented in two or more EDA systems 800.

EDA system 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion of or all the noted processes and/or methods is implemented as a standalone software application for execution by a processor. In some embodiments, a portion of or all the noted processes and/or methods is implemented as a software application that is a part of an additional software application. In some embodiments, a portion of or all the noted processes and/or methods is implemented as a plug-in to a software application. In some embodiments, at least one of the noted processes and/or methods is implemented as a software application that is a portion of an EDA tool. In some embodiments, a portion of or all the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

In some embodiments, based on the layout diagram generated by block 702 of FIG. 7, the IC manufacturing system 900 implements block 704 of FIG. 7 wherein at least one of (A) one or more semiconductor masks or (B) at least one component in a layer of an inchoate semiconductor integrated circuit is fabricated using manufacturing system 900. In some embodiments, the IC manufacturing system 900 implements the flowcharts of FIG. 5, or the like.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a cell region (of a device) includes: active regions extending in a first direction; gate segments and metal-to-source/drain-region (MD) contacts which extend in a second direction perpendicular to the first direction, are interspersed, and have portions over areas of the active regions; via-to-gate (VG) contacts over areas of the gate segments; via-to-MD-contact (VD) contacts over areas of the MD contacts; the VG contacts and the VD contacts being aligned correspondingly to alpha tracks extending in the first direction; in a first layer of metallization on a first side of the active regions, first routing (RTE) segments which extend in the first direction, are aligned correspondingly to the alpha tracks, and are correspondingly over the VG contacts or the VD contacts; and in a first buried layer of metallization on a second side of the active regions, first buried power grid segments which extend in the first direction; and first and second ones of the alpha tracks being adjacent to first and second boundaries of the cell region; at least a third one of the alpha tracks being between the first and second alpha tracks; the first alpha track being free from having any of the VG contacts aligned thereto; and the second alpha track being free from having any of the VD contacts aligned thereto.

In some embodiments, the gate segments are aligned correspondingly to beta tracks extending in the second direction; relative to the first direction, adjacent gate segments are separated from each other by a first pitch; relative to the second direction, adjacent first RTE segments are separated from each other by a second pitch; and regarding ones of the VD contacts that are aligned to a same one of the beta tracks (beta-coaligned VD contacts), adjacent beta-coaligned VD contacts are separated from each other by a gap having a size approximately equal to, or greater than, a lesser of the first pitch or twice the second pitch.

In some embodiments, the gate segments are aligned correspondingly to beta tracks extending in the second direction; relative to the first direction, adjacent gate segments are separated from each other by a first pitch; relative to the second direction, adjacent first RTE segments are separated from each other by a second pitch; regarding ones of the VG contacts that are aligned to a same one of the beta tracks (beta-coaligned VG contacts), adjacent beta-coaligned VG contacts are separated from each other by a gap having a size approximately equal to, or greater than, lesser of the first pitch or twice the second pitch.

In some embodiments, the cell region further includes: in a first layer of interconnection, first contacts aligned correspondingly to the alpha tracks and correspondingly over the first RTE segments, and wherein: one or more of the first RTE segments are first input/output (pin) segments; the first alpha track is free from having any of the first pin segments aligned thereto, and the second alpha track is free from having any of the first contacts aligned thereto.

In some embodiments, the gate segments are aligned correspondingly to beta tracks extending in the second direction; relative to the first direction, adjacent gate segments are separated from each other by a first pitch; relative to the second direction, adjacent first RTE segments are separated from each other by a second pitch; regarding ones of the first contacts that are aligned to a same one of the beta tracks (beta-coaligned first contacts), adjacent beta-coaligned first contacts are separated from each other by a gap having a size approximately equal to, or greater than, a lesser of the first pitch or twice the second pitch.

In some embodiments, the cell region further includes: in a second layer of metallization, second RTE segments which extend in the second direction, are aligned correspondingly to beta tracks, and are correspondingly over the first contacts, and wherein: relative to the second direction, adjacent first RTE segments are separated from each other by a first pitch; regarding ones of the second RTE segments that are aligned to a same one of the beta tracks (beta-coaligned second RTE segments), adjacent ends of beta-coaligned second RTE segments are separated from each other by a first gap equal to greater than the first pitch.

In some embodiments, the gate segments, the MD contacts, the VG contacts and the VD contacts of the cell region are arrangeable into a first arrangement or a second arrangement; and where arranged according the first arrangement or the second arrangement, the cell region is configured to perform a same function.

In some embodiments, where arranged according the first arrangement or the second arrangement, the cell region is configured to perform a same AND-OR-INVERT (AOI) function.

In some embodiments, a cell region (of a device) includes: active regions extending in a first direction; gate segments and metal-to-source/drain-region (MD) contacts which extend in a second direction perpendicular to the first direction, are interspersed, and have portions over areas of the active regions; via-to-gate (VG) contacts over areas of the gate segments; via-to-MD-contact (VD) contacts over areas of the MD contacts; the VG contacts and the VD contacts being aligned correspondingly to alpha tracks extending in the first direction; in a first layer of metallization on a first side of the active regions, first routing (RTE) segments which extend in the first direction, are aligned correspondingly to the alpha tracks, and are correspondingly over the VG contacts or the VD contacts, and one or more of the first RTE segments being first input/output (pin) segments; and in a first layer of interconnection, first contacts aligned correspondingly to the alpha tracks and correspondingly over the first RTE segments; in a first buried layer of metallization on a second side of the active regions, first buried power grid segments which extend in the first direction; and first and second ones of the alpha tracks being adjacent to first and second boundaries of the cell region; at least a third one of the alpha tracks being between the first and second alpha tracks; the first alpha track being free from having any of the VG contacts and any of the first pin segments aligned thereto; and the second alpha track being free from having any of the VD contacts and any of the first contacts aligned thereto.

In some embodiments, the gate segments are aligned correspondingly to beta tracks extending in the second direction; relative to the first direction, adjacent gate segments are separated from each other by a first pitch; relative to the second direction, adjacent first RTE segments are separated from each other by a second pitch; and regarding ones of the VD contacts that are aligned to a same one of the beta tracks (beta-coaligned VD contacts), adjacent beta-coaligned VD contacts are separated from each other by a gap having a size approximately equal to, or greater than, a lesser of the first pitch or twice the second pitch.

In some embodiments, the gate segments are aligned correspondingly to beta tracks extending in the second direction; relative to the first direction, adjacent gate segments are separated from each other by a first pitch; relative to the second direction, adjacent first RTE segments are separated from each other by a second pitch; regarding ones of the VG contacts that are aligned to a same one of the beta tracks (beta-coaligned VG contacts), adjacent beta-coaligned VG contacts are separated from each other by a gap having a size approximately equal to, or greater than, a lesser of the first pitch or twice the second pitch.

In some embodiments, the gate segments are aligned correspondingly to beta tracks extending in the second direction; relative to the first direction, adjacent gate segments are separated from each other by a first pitch; relative to the second direction, adjacent first RTE segments are separated from each other by a second pitch; regarding ones of the first contacts that are aligned to a same one of the beta tracks (beta-coaligned first contacts), adjacent beta-coaligned first contacts are separated from each other by a gap having a size approximately equal to, or greater than, a lesser of the first pitch or twice the second pitch.

In some embodiments, the cell region further includes: in a second layer of metallization, second RTE segments which extend in the second direction, are aligned correspondingly to beta tracks, and are correspondingly over the first contacts, and wherein: relative to the second direction, adjacent first RTE segments are separated from each other by a first pitch; regarding ones of the second RTE segments that are aligned to a same one of the beta tracks (beta-coaligned second RTE segments), adjacent ends of beta-coaligned second RTE segments are separated from each other by a first gap equal to greater than the first pitch.

In some embodiments, the gate segments, the MD contacts, the VG contacts and the VD contacts of the cell region are arrangeable into a first arrangement or a second arrangement; and where arranged according the first arrangement or the second arrangement, the cell region is configured to perform a same function.

In some embodiments, a method (of forming a cell region of a device) includes: forming active regions extending in a first direction; in a second direction perpendicular to the first direction, forming gate segments having portions over first areas of the active regions, and forming metal-to-source/drain-region (MD) contacts interspersed with the gate segments and having portions over second areas of the active regions; forming via-to-gate (VG) contacts over areas of the gate segments; forming via-to-MD-contact (VD) contacts over areas of the MD contacts; the VG contacts and the VD contacts being aligned correspondingly to alpha tracks extending in the first direction; in a first layer of metallization on a first side of the active regions, forming first routing (RTE) segments which extend in the first direction, are aligned correspondingly to the alpha tracks, and are correspondingly over the VG contacts or the VD contacts; in a first buried layer of metallization on a second side of the active regions, forming first buried power grid segments which extend in the first direction; and first and second ones of the alpha tracks being adjacent to first and second boundaries of the cell region; at least a third one of the alpha tracks being between the first and second alpha tracks; the forming via-to-gate (VG) contacts including the following, locating the VG contacts so that the first alpha track is free from having any of the VG contacts aligned thereto; and the forming via-to-MD-contact (VD) contacts including the following, locating the VD contacts so that the second alpha track is free from having any of the VD contacts aligned thereto.

In some embodiments, the forming gate segments includes the following, aligning the gate segments correspondingly to beta tracks extending in the second direction, and relative to the first direction, separating adjacent gate segments from each other by a first pitch; the forming metal-to-source/drain-region (MD) contacts includes the following, relative to the second direction, separating adjacent first RTE segments from each other by a second pitch; and the forming via-to-MD-contact (VD) contacts includes the following, aligning corresponding ones of the VD contacts to a same one of the beta tracks resulting in beta-coaligned VD contacts, and separating adjacent beta-coaligned VD contacts from each other by a gap having a size approximately equal to, or greater than, a lesser of the first pitch or twice the second pitch.

In some embodiments, the forming gate segments includes the following, aligning the gate segments correspondingly to beta tracks extending in the second direction, and relative to the first direction, separating adjacent gate segments from each other by a first pitch; the forming first routing (RTE) segments includes the following, relative to the second direction, separating adjacent first RTE segments from each other by a second pitch; and the forming via-to-gate (VG) contacts includes the following, aligning corresponding ones of the VG contacts to a same one of the beta tracks resulting in beta-coaligned VG contacts, and separating adjacent beta-coaligned VG contacts from each other by a gap having a size approximately equal to, or greater than, a lesser of the first pitch or twice the second pitch.

In some embodiments, the method further includes: in a first layer of interconnection, forming first contacts aligned correspondingly to the alpha tracks and correspondingly over the first RTE segments, and wherein: the forming first routing (RTE) segments includes forming one or more first input/output (pin) segments; the forming one or more first input/output (pin) segments includes the following, locating the one or more first pin segments so that the first alpha track is free from having any of the first pin segments aligned thereto; and the forming first contacts includes the following, locating the first contacts so that the second alpha track is free from having any of the first contacts aligned thereto.

In some embodiments, the forming gate segments includes the following, aligning the gate segments correspondingly to beta tracks extending in the second direction, and relative to the first direction, separating adjacent gate segments from each other by a first pitch; the forming first routing (RTE) segments includes the following, relative to the second direction, separating adjacent first RTE segments from each other by a second pitch; and the forming first contacts includes the following, aligning corresponding ones of the first contacts to a same one of the beta tracks resulting in beta-coaligned first contacts, and separating adjacent beta-coaligned first contacts from each other by a gap having a size approximately equal to, or greater than, a lesser of the first pitch or twice the second pitch.

In some embodiments, the method further includes: in a second layer of metallization, forming second RTE segments which extend in the second direction, are aligned correspondingly to beta tracks, and are correspondingly over the first contacts, and wherein: the forming first routing (RTE) segments includes the following, relative to the second direction, separating adjacent first RTE segments from each other by a first pitch; and the forming second RTE segments includes the following, aligning corresponding ones of the second RTE segments to a same one of the beta tracks resulting in beta-coaligned second RTE segments, and separating adjacent ends of beta-coaligned second RTE segments from each other by a first gap equal to greater than the first pitch.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

1. A cell region of a device, the cell region comprising:
active regions extending in a first direction;
gate segments and metal-to-source/drain-region (MD) contacts which extend in a second direction perpendicular to the first direction, are interspersed, and have portions over areas of the active regions;
via-to-gate (VG) contacts over areas of the gate segments;
via-to-MD-contact (VD) contacts over areas of the MD contacts;
the VG contacts and the VD contacts being aligned correspondingly to alpha tracks extending in the first direction;
in a first layer of metallization on a first side of the active regions, first routing (RTE) segments which extend in the first direction, are aligned correspondingly to the alpha tracks, and are correspondingly over the VG contacts or the VD contacts; and
in a first buried layer of metallization on a second side of the active regions, first buried power grid segments which extend in the first direction; and
first and second ones of the alpha tracks being adjacent to first and second boundaries of the cell region;
at least a third one of the alpha tracks being between the first and second alpha tracks;
the first alpha track being free from having any of the VG contacts aligned thereto; and
the second alpha track being free from having any of the VD contacts aligned thereto.

2. The cell region of claim 1, wherein:
the gate segments are aligned correspondingly to beta tracks extending in the second direction;
relative to the first direction, adjacent gate segments are separated from each other by a first pitch;
relative to the second direction, adjacent first RTE segments are separated from each other by a second pitch; and
regarding ones of the VD contacts that are aligned to a same one of the beta tracks (beta-coaligned VD contacts), adjacent beta-coaligned VD contacts are separated from each other by a gap having a size approximately equal to, or greater than, a lesser of the first pitch or twice the second pitch.

3. The cell region of claim 1, wherein:
the gate segments are aligned correspondingly to beta tracks extending in the second direction;
relative to the first direction, adjacent gate segments are separated from each other by a first pitch;
relative to the second direction, adjacent first RTE segments are separated from each other by a second pitch;
regarding ones of the VG contacts that are aligned to a same one of the beta tracks (beta-coaligned VG contacts), adjacent beta-coaligned VG contacts are separated from each other by a gap having a size approximately equal to, or greater than, lesser of the first pitch or twice the second pitch.

4. The cell region of claim 1, further comprising:
in a first layer of interconnection, first contacts aligned correspondingly to the alpha tracks and correspondingly over the first RTE segments; and
wherein:
one or more of the first RTE segments are first input/output (pin) segments;
the first alpha track is free from having any of the first pin segments aligned thereto, and
the second alpha track is free from having any of the first contacts aligned thereto.

5. The cell region of claim 4, wherein:
the gate segments are aligned correspondingly to beta tracks extending in the second direction;
relative to the first direction, adjacent gate segments are separated from each other by a first pitch;
relative to the second direction, adjacent first RTE segments are separated from each other by a second pitch;
regarding ones of the first contacts that are aligned to a same one of the beta tracks (beta-coaligned first contacts), adjacent beta-coaligned first contacts are separated from each other by a gap having a size approximately equal to, or greater than, a lesser of the first pitch or twice the second pitch.

6. The cell region of claim 4, further comprising:
in a second layer of metallization, second RTE segments which extend in the second direction, are aligned correspondingly to beta tracks, and are correspondingly over the first contacts; and
wherein:
relative to the second direction, adjacent first RTE segments are separated from each other by a first pitch;
regarding ones of the second RTE segments that are aligned to a same one of the beta tracks (beta-coaligned second RTE segments), adjacent ends of beta-coaligned second RTE segments are separated from each other by a first gap equal to greater than the first pitch.

7. The cell region of claim 1, wherein:
the gate segments, the MD contacts, the VG contacts and the VD contacts of the cell region are arrangeable into a first arrangement or a second arrangement; and
where arranged according the first arrangement or the second arrangement, the cell region is configured to perform a same function.

8. The cell region of claim 7, wherein:
where arranged according the first arrangement or the second arrangement, the cell region is configured to perform a same AND-OR-INVERT (AOI) function.

9. A cell region of a device, the cell region comprising:
active regions extending in a first direction;
gate segments and metal-to-source/drain-region (MD) contacts which extend in a second direction perpendicular to the first direction, are interspersed, and have portions over areas of the active regions;
via-to-gate (VG) contacts over areas of the gate segments;
via-to-MD-contact (VD) contacts over areas of the MD contacts;
the VG contacts and the VD contacts being aligned correspondingly to alpha tracks extending in the first direction;
in a first layer of metallization on a first side of the active regions, first routing (RTE) segments which extend in the first direction, are aligned correspondingly to the alpha tracks, and are correspondingly over the VG contacts or the VD contacts, and
one or more of the first RTE segments being first input/output (pin) segments; and
in a first layer of interconnection, first contacts aligned correspondingly to the alpha tracks and correspondingly over the first RTE segments;
in a first buried layer of metallization on a second side of the active regions, first buried power grid segments which extend in the first direction; and
first and second ones of the alpha tracks being adjacent to first and second boundaries of the cell region;
at least a third one of the alpha tracks being between the first and second alpha tracks;
the first alpha track being free from having any of the VG contacts and any of the first pin segments aligned thereto; and
the second alpha track being free from having any of the VD contacts and any of the first contacts aligned thereto.

10. The cell region of claim 9, wherein:
the gate segments are aligned correspondingly to beta tracks extending in the second direction;
relative to the first direction, adjacent gate segments are separated from each other by a first pitch;
relative to the second direction, adjacent first RTE segments are separated from each other by a second pitch; and
regarding ones of the VD contacts that are aligned to a same one of the beta tracks (beta-coaligned VD contacts), adjacent beta-coaligned VD contacts are separated from each other by a gap having a size approximately equal to, or greater than, a lesser of the first pitch or twice the second pitch.

11. The cell region of claim 9, wherein:
the gate segments are aligned correspondingly to beta tracks extending in the second direction;
relative to the first direction, adjacent gate segments are separated from each other by a first pitch;
relative to the second direction, adjacent first RTE segments are separated from each other by a second pitch; and
regarding ones of the VG contacts that are aligned to a same one of the beta tracks (beta-coaligned VG contacts), adjacent beta-coaligned VG contacts are separated from each other by a gap having a size approximately equal to, or greater than, a lesser of the first pitch or twice the second pitch.

12. The cell region of claim 9, wherein:
the gate segments are aligned correspondingly to beta tracks extending in the second direction;
relative to the first direction, adjacent gate segments are separated from each other by a first pitch;
relative to the second direction, adjacent first RTE segments are separated from each other by a second pitch;
regarding ones of the first contacts that are aligned to a same one of the beta tracks (beta-coaligned first contacts), adjacent beta-coaligned first contacts are separated from each other by a gap having a size approximately equal to, or greater than, a lesser of the first pitch or twice the second pitch.

13. The cell region of claim 9, further comprising:
in a second layer of metallization, second RTE segments which extend in the second direction, are aligned correspondingly to beta tracks, and are correspondingly over the first contacts; and
wherein:
relative to the second direction, adjacent first RTE segments are separated from each other by a first pitch;
regarding ones of the second RTE segments that are aligned to a same one of the beta tracks (beta-coaligned second RTE segments), adjacent ends of beta-coaligned second RTE segments are separated from each other by a first gap equal to greater than the first pitch.

14. The cell region of claim 9, wherein:
the gate segments, the MD contacts, the VG contacts and the VD contacts of the cell region are arrangeable into a first arrangement or a second arrangement; and
where arranged according the first arrangement or the second arrangement, the cell region is configured to perform a same function.

15. A method of forming a cell region of a device, the method comprising:
forming active regions extending in a first direction;
in a second direction perpendicular to the first direction,
forming gate segments having portions over first areas of the active regions, and
forming metal-to-source/drain-region (MD) contacts interspersed with the gate segments and having portions over second areas of the active regions;
forming via-to-gate (VG) contacts over areas of the gate segments;
forming via-to-MD-contact (VD) contacts over areas of the MD contacts;
the VG contacts and the VD contacts being aligned correspondingly to alpha tracks extending in the first direction;
in a first layer of metallization on a first side of the active regions,
forming first routing (RTE) segments which extend in the first direction, are aligned correspondingly to the alpha tracks, and are correspondingly over the VG contacts or the VD contacts;
in a first buried layer of metallization on a second side of the active regions,
forming first buried power grid segments which extend in the first direction; and
first and second ones of the alpha tracks being adjacent to first and second boundaries of the cell region;
at least a third one of the alpha tracks being between the first and second alpha tracks;
the forming via-to-gate (VG) contacts including the following,
locating the VG contacts so that the first alpha track is free from having any of the VG contacts aligned thereto; and
the forming via-to-MD-contact (VD) contacts including the following,
locating the VD contacts so that the second alpha track is free from having any of the VD contacts aligned thereto.

16. The method of claim 15, wherein:
the forming gate segments includes the following,
aligning the gate segments correspondingly to beta tracks extending in the second direction, and
relative to the first direction, separating adjacent gate segments from each other by a first pitch;
the forming metal-to-source/drain-region (MD) contacts includes the following,
relative to the second direction, separating adjacent first RTE segments from each other by a second pitch; and
the forming via-to-MD-contact (VD) contacts includes the following,
aligning corresponding ones of the VD contacts to a same one of the beta tracks resulting in beta-coaligned VD contacts, and
separating adjacent beta-coaligned VD contacts from each other by a gap having a size approximately equal to, or greater than, a lesser of the first pitch or twice the second pitch.

17. The method of claim 15, wherein:
the forming gate segments includes the following,
aligning the gate segments correspondingly to beta tracks extending in the second direction, and
relative to the first direction, separating adjacent gate segments from each other by a first pitch;
the forming first routing (RTE) segments includes the following,
relative to the second direction, separating adjacent first RTE segments from each other by a second pitch; and
the forming via-to-gate (VG) contacts includes the following,
aligning corresponding ones of the VG contacts to a same one of the beta tracks resulting in beta-coaligned VG contacts, and
separating adjacent beta-coaligned VG contacts from each other by a gap having a size approximately equal to, or greater than, a lesser of the first pitch or twice the second pitch.

18. The method of claim 15, further comprising:
in a first layer of interconnection, forming first contacts aligned correspondingly to the alpha tracks and correspondingly over the first RTE segments; and
wherein:
the forming first routing (RTE) segments includes forming one or more first input/output (pin) segments;
the forming one or more first input/output (pin) segments includes the following,
locating the one or more first pin segments so that the first alpha track is free from having any of the first pin segments aligned thereto; and
the forming first contacts includes the following,
locating the first contacts so that the second alpha track is free from having any of the first contacts aligned thereto.

19. The method of claim 18, wherein:
the forming gate segments includes the following,
aligning the gate segments correspondingly to beta tracks extending in the second direction, and
relative to the first direction, separating adjacent gate segments from each other by a first pitch;
the forming first routing (RTE) segments includes the following,
relative to the second direction, separating adjacent first RTE segments from each other by a second pitch; and
the forming first contacts includes the following,
aligning corresponding ones of the first contacts to a same one of the beta tracks resulting in beta-coaligned first contacts, and
separating adjacent beta-coaligned first contacts from each other by a gap having a size approximately equal to, or greater than, a lesser of the first pitch or twice the second pitch.

20. The method of claim 18, further comprising:
in a second layer of metallization,
forming second RTE segments which extend in the second direction, are aligned correspondingly to beta tracks, and are correspondingly over the first contacts; and
wherein:
the forming first routing (RTE) segments includes the following,
relative to the second direction, separating adjacent first RTE segments from each other by a first pitch; and
the forming second RTE segments includes the following,
aligning corresponding ones of the second RTE segments to a same one of the beta tracks resulting in beta-coaligned second RTE segments, and
separating adjacent ends of beta-coaligned second RTE segments from each other by a first gap equal to greater than the first pitch.
